(19) United States
(12) Patent Application Publication
(10) Pub. No.: US 2023/0324435 A1
(43) Pub. Date: Oct. 12, 2023

(54) Pin-Type Probes for Contacting Electronic Circuits and Methods for Making Such Probes

(71) Applicant: Microfabrica Inc., Van Nuys, CA (US)

(72) Inventors: Arun S. Veeramani, Vista, CA (US); Ming Ting Wu, San Jose, CA (US); Uri Frodis, Los Angeles, CA (US); Heath A. Jensen, West Hills, CA (US)

(73) Assignee: Microfabrica Inc., Van Nuys, CA (US)

(21) Appl. No.: 18/299,648

(22) Filed: Apr. 12, 2023

Related U.S. Application Data
(63) Continuation of application No. 17/532,959, filed on Nov. 22, 2021, now abandoned.
Application No. 17/532,959 is a continuation of application No. 16/666,377, filed on Oct. 28, 2019, now abandoned.
(60) Provisional application No. 62/756,574, filed on Nov. 6, 2018.
(60) Provisional application No. 62/751,532, filed on Oct. 26, 2018.

(51) Int. Cl. G01R 1/067; G01R 1/073; G01R 3/00

(52) U.S. Cl. CPC G01R 1/06722; G01R 1/06738; G01R 1/07314; G01R 1/06744; G01R 3/00; G01R 1/06761

(57) ABSTRACT

Pin probes and pin probe arrays are provided that allow electric contact to be made with selected electronic circuit components. Some embodiments include one or more compliant pin elements located within a sheath. Some embodiments include pin probes that include locking or latching elements that may be used to fix pin portions of probes into sheaths. Some embodiments provide for fabrication of probes using multi-layer electrochemical fabrication methods.

### RELATED APPLICATIONS

The following list sets forth the priority claims for the instant application along with filing dates, patent numbers, and issue dates as appropriate:
This application is a continuation of U.S. application Ser. No. 17/532,959, filed on Nov. 22, 2021, which is currently pending (Microfabrica Docket No. P-US378-B-MF);
U.S. application Ser. No. 17/532,959 is a continuation of U.S. application Ser. No. 16/666,377, filed on Oct. 28, 2019, which is lapsed (Microfabrica Docket No. P-US378-A-M F);
U.S. application Ser. No. 16/666,377 claims benefit of 62/756,574, filed on Nov. 6, 2018, which is currently expired (P-US367-B-MF); and
U.S. application Ser. No. 16/666,377 claims benefit of 62/751,532, filed on Oct. 26, 2018, which is currently expired (P-US367-A-MF).

Each of the listed applications is incorporated herein by reference as if set forth in full herein including any appendices attached thereto.

### FIELD OF THE INVENTION

Embodiments of the present invention relate to microprobes (e.g. for use in the wafer level testing or socket testing of integrated circuits, or for use in making electrical connections to PCBs or other electronic components) and more particularly to pin-like microprobes (i.e. microprobes that have vertical or longitudinal heights that are much greater than their widths). In some embodiments, the microprobes are produced by electrochemical fabrication methods and more particularly by multi-layer multi-material electrochemical fabrication methods.

### BACKGROUND OF THE INVENTION

Probes:

Numerous electrical contact probe and pin configurations have been commercially used or proposed, some of which may qualify as prior art and others of which do not qualify as prior art. Examples of such pins, probes, and methods of making are set forth in the following patent applications, publications of applications, and patents:
A. U.S. patent application Ser. No. 10/772,943, filed on Feb. 4, 2004, published as US App Pub No. 2005-0104609 on May 19, 2005, and entitled “Electrochemically Fabricated Microprobes” by Arat, et al.
B. U.S. patent application Ser. No. 10/949,738, filed on Sep. 24, 2019, published as US App Pub No. 2006-0006888 on Jan. 12, 2006, and entitled “Electrochemically Fabricated Microprobes” by Kruglick, et al.
C. U.S. patent application Ser. No. 11/028,945, filed on Jan. 3, 2005, issued as U.S. Pat. No. 7,640,651 on Jan. 5, 2010, and entitled “A Fabrication Process for Co-Fabricating a Multilayer Probe Array and a Space Transformer” by Cohen, et al.
D. U.S. patent application Ser. No. 11/028,960, filed on Jan. 3, 2005, issued as U.S. Pat. No. 7,265,565 on Sep. 4, 2007, and entitled “Cantilever Microprobes for Contacting Electronic Components and Methods for Making Such Probes” by Chen, et al.
E. U.S. patent application Ser. No. 11/029,180, filed on Jan. 3, 2005, published as US Pub App No. 2005-0184748 on Aug. 25, 2005, and entitled “Pin-Type Probes for Contacting Electronic Circuits and Methods for Making Such Probes” by Chen, et al.
F. U.S. patent application Ser. No. 11/029,217, filed on Jan. 3, 2005, issued as U.S. Pat. No. 7,412,767 on Aug. 19, 2008, and entitled “Microprobe Tips and Methods for Making” by Kim, et al.
G. U.S. patent application Ser. No. 11/173,241, filed on Jun. 30, 2005, published as US Pub App No. 2006-0108678 on May 25, 2006, and entitled “Probe Arrays and Method for Making” by Kumar, et al.
H. U.S. patent application Ser. No. 11/178,145, filed on Jul. 7, 2005, issued as U.S. Pat. No. 7,273,812 on Sep. 25, 2007, and entitled “Microprobe Tips and Methods for Making” by Kim, et al.
I. U.S. patent application Ser. No. 11/325,404, filed on Jan. 3, 2006, published as US Pub App No. 2006-0238209 on Oct. 26, 2006, and entitled “Electrochemically Fabricated Microprobes” by Chen, et al.
J. U.S. patent application Ser. No. 14/986,500, filed on Dec. 31, 2015, published as US Pub App No. 2016-0231356 on Aug. 11, 2016, and entitled “Multi-Layer, Multi-Material Micro-Scale and Millimeter-Scale Devices with Enhanced Electrical and/or Mechanical Properties” by Wu, et al.
K. U.S. patent application Ser. No. 16/172,354, filed on Oct. 18, 2018, published as US Pub App No. 2019-0204354 on Jul. 4, 2019, and entitled “Pin-Type Probes for Contacting Electronic Circuits and Methods for Making Such Probes” by Chen, et al.
L. U.S. patent application Ser. No. 16/584,818, filed on Sep. 26, 2019 and entitled “Probes Having Improved Mechanical and/or Electrical Properties for Making Contact between Electronic Circuit Elements and Methods for Making” by Smalley
M. U.S. patent application Ser. No. 16/584,863, filed on Sep. 26, 2019 and entitled “Probes Having Improved Mechanical and/or Electrical Properties for Making Contact between Electronic Circuit Elements and Methods for Making” by Frodis
N. U.S. Patent App No. 62/805,589, filed on Feb. 14, 2019 and entitled “Multi-Beam Vertical Probes with Independent Arms Formed of a High Conductivity Metal for Enhancing Current Carrying Capacity and Methods for Making Such Probes” by Frodis

Each of these applications, publications, and patents is incorporated herein by reference as if set forth in full herein as are any teachings set forth in each of their prior applications.

Electrochemical Fabrication:

Electrochemical fabrication techniques for forming three-dimensional structures from a plurality of adhered layers are being commercially pursued by Microfabrica® Inc. (formerly MEMGen Corporation) of Van Nuys, California under the process names EFAB and MICA FREEFORM™.

Various electrochemical fabrication techniques were described in U.S. Pat. No. 6,027,630, issued on Feb. 22, 2000 to Adam Cohen.

Another method for forming microstructures using electrochemical fabrication techniques is taught in U.S. Pat. No. 5,190,637 to Henry Guckel, entitled “Formation of Microstructures by Multiple Level Deep X-ray Lithography with Sacrificial Metal Layers.

Electrochemical Fabrication provides the ability to form prototypes and commercial quantities of miniature objects, parts, structures, devices, and the like at reasonable costs and in reasonable times. In fact, Electrochemical Fabrication is an enabler for the formation of many structures that were hitherto impossible to produce. Electrochemical Fabrication opens the spectrum for new designs and products in many industrial fields. Even though Electrochemical Fabrication offers this new capability and it is understood that Electrochemical Fabrication techniques can be combined with designs and structures known within various fields to produce new structures, certain uses for Electrochemical Fabrication provide designs, structures, capabilities and/or features not known or obvious in view of the state of the art.

A need exists in various fields for miniature devices having improved characteristics, reduced fabrication times, reduced fabrication costs, simplified fabrication processes, greater versatility in device design, improved selection of materials, improved material properties, more cost effective and less risky production of such devices, and/or more independence between geometric configuration and the selected fabrication process.

### SUMMARY OF THE INVENTION

It is an object of some embodiments of the invention to provide pin probes (e.g. pogo pin probes) with improved characteristics.

It is an object of some embodiments of the invention to provide pin probes that are more reliable.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not necessarily intended that all objects be addressed by any single aspect of the invention even though that may be the case regarding some aspects.

In a first aspect of the invention a pin probe for making electrical contact to an electronic circuit element includes: (A) a pin element, including: (1) a first contact tip; (2) a second contact tip; and (2) a compliant portion having a first end functionally connected to the first contact tip, and a second end functionally connected to the second contact tip; (B) an inner sheath which encases a portion of the pin element without significantly restricting the compliance of the compliant portion along a longitudinal axis of the probe extending from the first contact tip to the second contact tip; (C) an outer sheath; and (D) at least one dielectric element that spaces the inner sheath from the outer sheath and provides for electrical isolation of the inner sheath and the outer sheath.

Numerous variations of the first aspect of the invention exist and include, for example: (1) the compliant portion including a multi-turn spring; (2) variation 1 wherein the inner sheath inhibits the multi-turn compliant element from contacting the outer sheath during compression of one of the first contact tip and the second contact tip toward the other the contact tips; (3) variation 1 wherein the inner sheath includes a top surface, a bottom surface and two side surfaces that that inhibit non-longitudinal compression of the compliant element; (4) the compliant element including a spring configuration selected from the group consisting of: (a) a rectangular coil; (b) an a plurality of joined S-shaped spring elements; (c) a plurality of compressible and contacting but un-joined compliant elements; (d) a plurality of joined rectangular S-shaped elements; (e) a plurality of S-shaped elements with complete S-shapes defined within a plane of a single layer; (f) a plurality of S-shaped elements with their S-shapes defined by only portions of the S-shape existing within a single layer and a plurality of at least three layers required to define a complete S-shape; (g) a plurality of curved S-shaped elements with each S-shape having regions of differing width, such that stress within each S-shape is move uniformly applied than it would be for S-shapes of uniform width; (5) the at least one dielectric including a plurality of dielectrics spaced along a length dimension of the inner sheath; (6) the at least one dielectric including a plurality of dielectric elements separated by a height of the inner sheath; (7) the at least one dielectric includes a plurality of dielectric elements separated by a width of the inner sheath; (8) the inner sheath has a configuration that includes a feature selected from the group consisting of (a) at least one intermediate opening along a length dimension of the inner sheath; (b) a plurality of intermediate openings along a length dimension of the inner sheath; (c) at least one opening along a length dimension of the probe wherein the opening is located in a position that inhibits the spring from moving into the opening during compression of the spring; and (d) at least one opening along a length dimension of the probe wherein the opening has a size that inhibits the spring from moving into the opening during compression of the spring; and (9) upon compression of the compliant element contact is made between the compliant element and the inner sheath such that upon use, current flows between the first tip and the second tip via the sheath.

Other variations include those derived from combinations of the first aspect with the features of the other aspects set forth herein, mutatis mutandis, so long as such combinations do not completely remove the advantages or functionality while others may be derived from combinations of the variations of the first aspect with the variations of the other aspects.

In a second aspect of the invention a pin probe for making electrical contact to an electronic circuit element includes: (A) a pin element having a first end and a second end, comprising: (1) a first contact tip located at the first end; (2) a compliant portion having a first end functionally connected to the first contact tip, and a second end functionally connected to the second contact tip; (B) an inner sheath which encases a portion of the pin element without significantly restricting the compliance of the compliant portion along a longitudinal axis of the probe extending from the first contact tip to the second end of the pin element; (C) an outer sheath; (D) at least one dielectric element that spaces the inner sheath from the outer sheath and provides for electrical isolation of the inner sheath and the outer sheath.

Numerous variations of the second aspect of the invention exist and include, for example those noted in association with the first aspect of the invention.

In a third aspect of the invention a pin probe for making electrical contact to an electronic circuit element includes: (A) a pin element having a first end, including: (1) a first contact tip located at the first end; (2) a compliant portion having a first end functionally connected to the first contact tip; (B) a sheath which encases a portion of the pin element and comprising a second tip at an end opposite to that of the first contact tip wherein the sheath functionally connects to the compliant portion to provide a complaint outward biasing of the first contact tip relative to the second tip.

Numerous variations of the third aspect of the invention are possible and include: for example: (1) between the first contact tip and the compliant portion a rigid intermediate region exists where extending from the rigid intermediate region at least one compliant sliding contact element exists that provides a conductive path between the first contact tip, a body of the sheath, and the second tip when the first contact tip is compressed toward the second contact tip; (2) the at least one compliant sliding contact element of the first variation includes two oppositely oriented compliant sliding contact elements that provide compliant contact the sheath; (3) the sliding contact elements are not forced into contact with the sheath when no compression of the first tip toward the second tip exists; (4) at least one of the first contact tip or the second tip includes a curved contact in at least one dimension that is configured to provide stable mating with a bumped contact on an electronic component; (5) the sheath is an inner sheath that is electrically isolated from an outer sheath and can slide relative to the outer sheath when the second tip makes contact with an electronic circuit element.

Other variations include those derived from combinations of the third aspect with the features of the other aspects set forth herein, mutatis mutandis, so long as such combinations do not completely remove the advantages or functionality while others may be derived from combinations of the variations of the third aspect with the variations of the other aspects.

In a fourth aspect of the invention a pin probe for making electrical contact to an electronic circuit element includes: (A) at least two compliant spring elements; (B) a first pin element having a first end for engaging an electronic circuit element and a second sliding engagement end, wherein the first pin is connected to first ends of the two compliant spring elements; (C) a second pin element having a second end for contacting a second electronic circuit element and having a first sliding engagement end, wherein the second pin is connected to the second end of the two compliant spring elements, and wherein the second sliding engagement end of the first pin element and the first sliding engagement end of the second pin probe can be made to slidably engage one another upon compression of the first end and the second end toward one another such that a conductive path through the first pin to the second pin is provided, wherein one of the at least two compliant spring elements is located on a first side of the first and second pin elements and the other of the compliant spring elements is located on a second side of the first and second pin elements.

Numerous variations of the fourth aspect of the invention are possible and include: for example: (1) at least one of the at least two compliant spring elements includes a multi-turn serpentine spring; (2) the at least one of the at least two compliant springs are compressed as the first and second tips are compressed toward one another; (3) at least one of the at least two spring elements are stretched as the first and second tips are compressed toward one another; (4) the at least two compliant springs include at least four complaint springs; (5) the springs are inhibited from bowing outward as the first and second tips are compressed toward one another; (6) inclusion of an outer sheath relative to which at least one of the first and second tips can move, wherein the first and second pin elements are electrically separated from the outer sheath by at least one dielectric spacer; (7) the engagement elements of the first and second pin elements are not in engaged with one another until the pins are compressed toward one another and a compliant element of at least one of the pins is made to engage a locking element on another of the pins; (8) the engagement elements once engaged are locked in a slidable position under normal operating conditions.

Other variations include those derived from combinations of the fourth aspect with the features of the other aspects set forth herein, mutatis mutandis, so long as such combinations do not completely remove the advantages or functionality while others may be derived from combinations of the variations of the fourth aspect with the variations of the other aspects.

In a fifth aspect of the invention a combined probe having a pair of pin probes for making electrical contact to a single contact on a first circuit element and two different contacts on a second circuit element includes: (A) a first pin probe in a first sheath; (B) a second pin probe in a second sheath; (C) a dielectric spacer separating and electrically isolating the first and second pins; wherein a first ends on each of the first and second pins are fixedly positioned relative to one another for contacting a single contact on the first circuit element; and wherein the second ends on each of first and second pins are compliantly connected to the first ends of their respective pins wherein upon pressing against different contacts on the second circuit elements, each pin may undergo a different amount of compliant compression relative to its first end to ensure an adequate electrical connection between the contacts of the first and second circuit elements.

Numerous variations of the fifth aspect of the invention are possible and include for example the variations associated with the other aspects of the invention, mutatis mutandis, so long as such combinations do not completely remove the advantages or functionality

In a sixth aspect of the invention a pin probe for making electrical contact to an electronic circuit element includes: (A) a pin element, including: (1) a first contact tip; (2) a second contact tip; and (2) a compliant portion having a first end functionally connected to the first contact tip, and a second end functionally connected to the second contact tip; (B) an inner sheath which encases a portion of the pin element without significantly restricting the compliance of the compliant portion along a longitudinal axis of the probe from the first contact tip to a first connection point between the compliant portion and the inner sheath and from the second contact tip to a second connection point between the compliant portion and the inner sheath; (C) an outer sheath; (D) at least one dielectric element that spaces the inner sheath from the outer sheath and provides for electrical isolation of the inner sheath and the outer sheath.

Numerous variations of the sixth aspect of the invention are possible and include: for example: (1) the compliant portion includes a multi-turn spring; (2) the inner sheath inhibits the multi-turn compliant element from contacting the outer sheath during compression of one of the first contact tip and the second contact tip toward the other contact tip; (3) the inner sheath comprises a top surface, a bottom surface and two side surfaces that that inhibit non-longitudinal compression of the compliant element; (4) the compliant element comprises a spring configuration selected from the group consisting of: (a) a rectangular coil; (b) an a plurality of joined S-shaped spring elements; (c) a plurality of compressible and contacting but un-joined compliant elements; (d) a plurality of joined rectangular S-shaped elements; (e) a plurality of S-shaped elements with complete S-shapes defined within a plane of a single layer; (f) a plurality of S-shaped elements with their S-shapes defined by only portions of the S-shape existing within a single layer and a plurality of at least three layers required to define a complete S-shape; and (g) a plurality of curved S-shapes with each S-shape having regions of differing width, such that stress within each S-shape is move uniformly applied than it would be for S-shapes of uniform width; (5) the at least one dielectric comprises a plurality of dielectrics spaced along a length dimension of the inner sheath; (6) the at least one dielectric comprises a plurality of dielectric elements separated by a height of the inner sheath; (7) the at least one dielectric comprises a plurality of dielectric elements separated by a width of the inner sheath; (8) the inner sheath has a configuration that includes a feature selected from the group consisting of (a) at least one intermediate opening along a length dimension of the inner sheath; (b) a plurality of intermediate openings along a length dimension of the inner sheath; (c) at least one opening along a length dimension of the probe wherein the opening is located in a position that inhibits the spring from moving into the opening during compression of the spring; and (d) at least one opening along a length dimension of the probe wherein the opening has a size that inhibits the spring from moving into the opening during compression of the spring; and (9) the first and second connection points are the same connection point.

Other variations include those derived from combinations of the sixth aspect with the features of the other aspects set forth herein, mutatis mutandis, so long as such combinations do not completely remove the advantages or functionality while others may be derived from combinations of the variations of the sixth aspect with the variations of the other aspects.

In a seventh aspect of the invention a pin probe for making electrical contact to an electronic circuit element includes: (A) a pin element, including: (1) a first contact tip; (2) a second contact tip; and (2) a compliant portion having a first end functionally connected to the first contact tip, and a second end functionally connected to the second contact tip; (B) an outer sheath; (C) at least two retention elements that slidably engage the pin in proximity to the first contact tip and in proximity to the second contact tip respectively; (D) at least one dielectric element associated with at least one retention element that provides for fixed spacing between the respective retention element and the outer sheath by a configuration selected from the group consisting of: (1) a reentrant engagement of the dielectric with an opening in the outer sheath; (2) a reentrant engagement of the dielectric with an opening in the respective retention element; (3) a reentrant engagement between a feature of the outer sheath and an opening in the dielectric element; (4) a reentrant engagement with a feature of the respective retention element and an opening in the dielectric element; and (5) a reentrant engagement between the dielectric and both the outer sheath and respective retention element.

Numerous variations of the seventh aspect of the invention are possible and include, for example: (1) the at least one dielectric element including at least two dielectric elements; (2) the at least one dielectric element including at least two dielectric elements for each of the first contact tip and the second contact tip; (3) the compliant portion including at least two compliant portions connected serially by an intermediate non-compliant portion; (4) at least one intermediate non-compliant portion being slidably held by an additional engagement element that connects to the outer sheath by at least one dielectric element.

Other variations include those derived from combinations of the seventh aspect with the features of the other aspects set forth herein, mutatis mutandis, so long as such combinations do not completely remove the advantages or functionality while others may be derived from combinations of the variations of the seventh aspect with the variations of the other aspects.

In an eighth aspect of the invention a pin probe for making electrical contact to an electronic circuit element includes: (A) at least one compliant spring element; (B) a first pin element having a first end for engaging an electronic circuit element and a second sliding engagement end, wherein the first pin is connected to a first end of the at least one compliant spring element; (C) a second contact element having a second end for contacting a second electronic circuit element and having a first sliding engagement end; (D) an outer sheath surrounding a portion of the first pin element and the second contact element where both the first pin element and the second contact element are electrically isolated from the outer sheath and where the second contact element is fixedly mounted to the outer sheath via at least one dielectric spacer; wherein a second end of the at least one compliant spring element is connected to at least one of the outer sheath and the second contact element, wherein upon relative compression of the first end of the first pin element and the second contact element toward one another against a force provided by the at least one compliant spring element, a conductive path is provided from the first pin element to the second contact element while maintaining electrical isolation of both the first pin element and the second contact element from the outer sheath.

Numerous variations of the eighth aspect of the invention are possible and include: for example: (1) the at least one compliant spring element includes at least two compliant elements extending in parallel on either side of the first pin element; (2) the at least one compliant spring element is connected to the first pin element via a dielectric element; (3) the at least one compliant spring element is connected to sheath via a dielectric element; and (4) the first pin element is slidably held in position relative to the sheath by a retention element in combination with a dielectric element that provides for electrical isolation.

Other variations include those derived from combinations of the eighth aspect with the features of the other aspects set forth herein, mutatis mutandis, so long as such combinations do not completely remove the advantages or functionality while others may be derived from combinations of the variations of the eighth aspect with the variations of the other aspects.

In a ninth aspect of the invention a pin probe for making electrical contact to an electronic circuit element comprising: (A) at least one compliant spring element; (B) a first pin element having a first end for engaging a first electronic circuit element and a second sliding engagement end, wherein the first pin is connected to at least one of the at least one compliant spring element; (C) a second pin element having a second end for engaging a second electronic circuit element and a first sliding engagement end, wherein the second pin is connected to at least one of the at least one compliant spring element; (D) an outer sheath surrounding a portion of the first pin element and the second pin element where both the first pin element and the second contact element are electrically isolated from the outer sheath via retainers that allow sliding and provide for a dielectric barrier between the pins and the sheath, wherein upon longitudinal compression of the first pin and second pin toward one another a slidable compliant contact is engaged that provides for a conductive path from the first electronic circuit element to the second electronic circuit element.

Numerous variations of the ninth aspect of the invention are possible and include: for example: (1) the at least one compliant spring element comprises at least two compliant elements extending in parallel on either side of the first pin element and the second pin element wherein each of the compliant elements connect to both the first and second pins; (2) the at least one compliant spring element includes at least two compliant elements extending in parallel on either side of the first pin element and the second pin element wherein one of the compliant elements connects to the first pin and to the outer sheath via at least one dielectric spacer and where another of the compliant elements connects to the second pin and to the outer sheath via at least one dielectric spacer; (3) variation 2 with each of the dielectric spacers separating their respective pin from the their respective compliant element; and (4) each of the dielectric spacers separate their respective compliant spring elements from the outer sheath.

Other variations include those derived from combinations of the ninth aspect with the features of the other aspects set forth herein, mutatis mutandis, so long as such combinations do not completely remove the advantages or functionality while others may be derived from combinations of the variations of the ninth aspect with the variations of the other aspects.

In a tenth aspect of the invention a pin probe for making electrical contact to an electronic circuit element, includes: (A) a pin element in functional contact with a first tip and a second tip on opposite end of the pin; (B) an outer sheath surrounding at least part of the pin element and separated from the pin element by a plurality of dielectric spacers, wherein the outer sheath comprises a plurality of relatively rigid regions spaced longitudinally from one another, and wherein the sheath comprises a flexible configuration between the relatively rigid regions that allows the sheath to bend along at least one plane to provide compliance for the pin probe when contacting electronic circuit elements, wherein the dielectric spacers at located in at least a portion of the relative rigid regions.

Numerous variations of the tenth aspect of the invention are possible and include: for example: (1) the relatively rigid are located in proximity to the ends of the outer sheath; (2) variation 1 wherein at least one additional relatively rigid region is located in an intermediate region along with at least one dielectric spacer; (3) the flexible configuration comprises a configuration selected from the group consisting of: (a) rectangular coil spring; (b) notches that extend perpendicular to the longitudinal direction and allow motion in a single plane; (c) notches that allow motion in a single plane but only in a single direction; and (d) notches with stress relief configurations.

Other variations include those derived from combinations of the tenth aspect with the features of the other aspects set forth herein, mutatis mutandis, so long as such combinations do not completely remove the advantages or functionality while others may be derived from combinations of the variations of the tenth aspect with the variations of the other aspects.

Other aspects of the invention will be understood by those of skill in the art upon review of the teachings herein. Other aspects of the invention may involve combinations of the above noted aspects of the invention. These other aspects of the invention may provide various combinations of the aspects presented above as well as provide other configurations, structures, functional relationships, and processes that have not been specifically set forth above but are taught by other specific teachings set forth herein or by the teachings set forth herein as a whole.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 1I respectively depict the state of the process after formation of the multiple layers of the structure and after release of the structure from the sacrificial material.

FIGS. 2A-2R provide various views of a sample coaxial pin-probe according to an embodiment wherein the pin probe includes a pin element that is biased to move within a first conductive sheath which is separated from a second surrounding conductive sheath by dielectric spacers.

FIGS. 3A-3O provide various views of a sample pin probe including a pin element and a sheath that can shunt current from a moveable tip at one end of the pin element to the sheath and then to a fixed tip at the other end of the probe.

FIGS. 4A-4H provide various views of another sample pin probe with a single moving tip and fixed tip with a stacked buckled plate-like spring configuration.

FIGS. 5A-5I provides another sample pin probe with a single moving tip and a fixed tip with another alternative spring configuration including a pair of serpentine springs located on either side of a relative rigid guide member wherein the pin element includes a fabrication position that is different from a use position wherein the moving pin moves from the fabrication position to the use position via movement past a compliant engagement element that inhibits the tip from extending from a useable range back to the fabrication position after initial loading.

FIGS. 6A-6B provides another sample pin probe including a pair of electrically isolated probes that include moving tips on one side and fixed tips on the other wherein the moving tips are rigidly joined for coincident movement or are loosely joined for substantially coincident movement for Kelvin type probing.

FIGS. 7A-7H provide various views of a shielded pseudo coaxial probe according to another embodiment of the invention that includes a central conductor and a fixed length shielding conductor wherein the central conductor includes lower and upper fixed length surfaces connected to the shield conductor by dielectric spacers (e.g. at each end and at an intermediate location) and which are joined to one another at each end via side wall elements through which a passage extends and are spaced from one another by a gap in a longitudinally extending central region in which a meandering spring is compressibly located, connected at an intermediate location to the lower and upper surfaces, and connected to contact tip elements on either end that extend through the passage and that include stop elements that keep the contact tip elements from extending too far out of the shield element via an interaction between the stop elements and the passage side walls when the tips are not contacting surfaces to be electrically connected and the spring is not under a compressive load.

FIGS. 8A-8C depict a spring comprising a plurality of S-shaped segments (FIG. 8A) that may be used in various embodiments of the invention wherein the each S-shaped segment (FIG. 8B), or at least selected S-Shaped segments, are configured to have widths of varying dimension (some narrower regions and some wider regions) that may be designed and formed to optimize performance of the spring such as stress loading as shown in the stress simulation image of FIG. 8C or to optimize other parameters singly or in combinations (e.g. length, spring constant, over travel, current carrying capacity, and the like).

FIGS. 9A-9E provide various views of a shielded pseudo coaxial probe of another embodiment of the invention, similar in some respects to the probe of FIGS. 7A-7H with the notable exception that the upper and lower surfaces of the central conductor are removed in favor of using the spring as the central conductor wherein the central conductor is retained at each end by rectangular structures with central passages where the rectangular structures are held in position relative to the outer conductive shield by dielectric spacers that may engage the shield as well as the rectangular structures with reentrant features or simply features of varying width along a radial length of the dielectric so as to lock the rectangular structures, the shield and the dielectric together mechanically thus reducing the need for bonding strength alone to hold adjacent elements or structures in place.

FIGS. 10A-10D provide another example of a pseudo coaxial probe but where only one end has significant compliance.

FIGS. 11A-11I provide various views of an embodiment similar to that of FIGS. 10A-10D with the primary exception being that the probe has two compliant contact elements and the sliding contact elements of the central conductive bar are located more centrally along the longitudinal length of the probe and as with the embodiment of FIGS. 10A-10D the probe is provided with a pair of compressible springs with one located below and the other above the central conductor and inside the outer shield.

FIGS. 12A-12D provide various views of a pseudo coaxial probe that includes a relatively incompressible central conductor that can elastically bend or buckle which is located within a cage-like outer shielding conductor, and is spaced from the outer conductor by dielectric elements that are attached to the central or to the outer conductor where the outer conductor includes features that allow compliance along one axis that is substantially perpendicular to a local longitudinal axis of the probe but not along the other axis which is locally perpendicular to both.

### DETAILED DESCRIPTION OF PREFERRED EMBODIMENTS

Electrochemical Fabrication in General

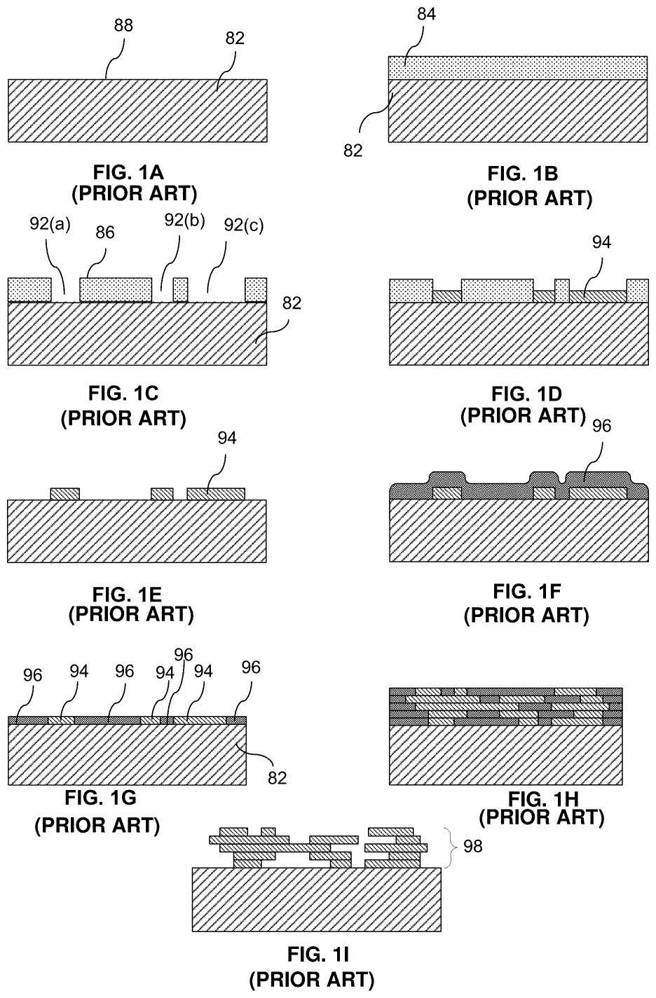

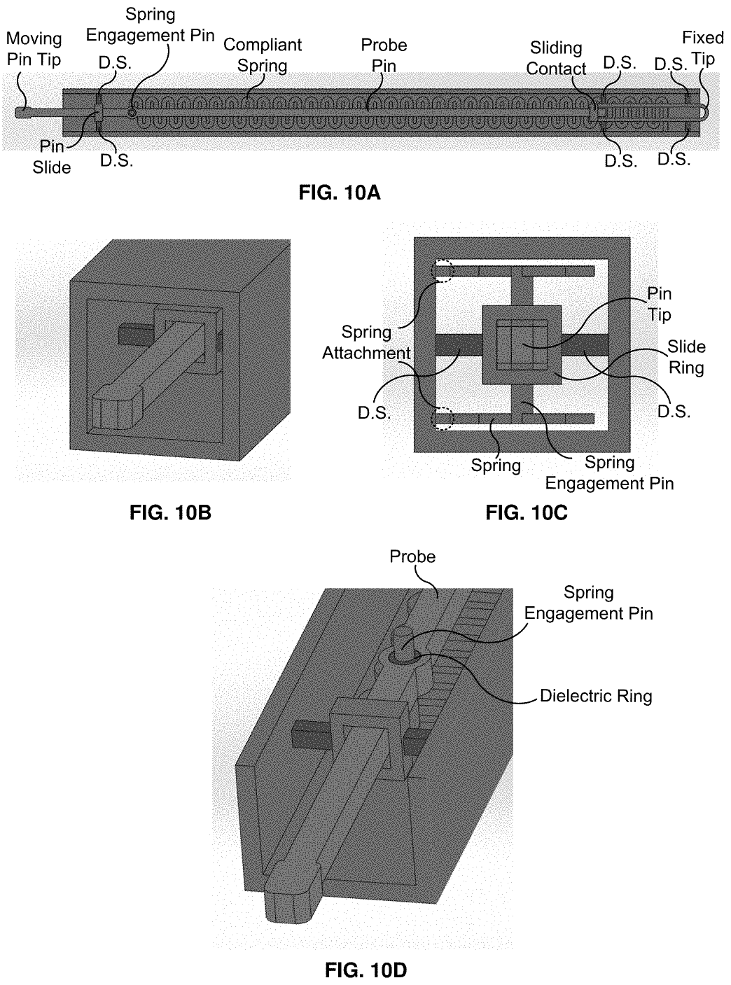

FIGS. 1A-1I illustrate side views of various states in an alternative multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metal form part of the layer. In FIG. 1A a side view of a substrate 82 having a surface 88 is shown, onto which patternable photoresist 84 is cast as shown in FIG. 1B. In FIG. 10, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 1D a metal 94 (e.g. nickel) is shown as having been electroplated into the openings 92(a)-92(c). In FIG. 1E the photoresist has been removed (i.e. chemically stripped) from the substrate to expose regions of the substrate 82 which are not covered with the first metal 94. In FIG. 1F a second metal 96 (e.g. silver) is shown as having been blanket electroplated over the entire exposed portions of the substrate 82 (which is conductive) and over the first metal 94 (which is also conductive). FIG. 1G depicts the completed first layer of the structure which has resulted from the planarization of the first and second metals down to a height that exposes the first metal and sets a thickness for the first layer. In FIG. 1H the result of repeating the process steps shown in FIGS. 1B-1G several times to form a multi-layer structure is shown where each layer consists of two materials. For most applications, one of these materials is removed as shown in FIG. 1I to yield a desired 3-D structure 98 (e.g. component or device).

Various embodiments of various aspects of the invention are directed to formation of three-dimensional structures from materials, some, or all, of which may be electrodeposited or electroless deposited (as illustrated in FIGS. 1A-1I and as discussed in various patent applications incorporated herein by reference). Some of these structures may be formed from a single build level formed from one or more deposited materials while others are formed from a plurality of build layers, each including at least two materials (e.g. two or more layers, more preferably five or more layers, and most preferably ten or more layers). In some embodiments, layer thicknesses may be as small as one micron or as large as fifty microns. In other embodiments, thinner layers may be used while in other embodiments, thicker layers may be used. In some embodiments, microscale structures have lateral features positioned with 0.1-10 micron level precision and minimum features size on the order of microns to tens of microns. In other embodiments, structures with less precise feature placement and/or larger minimum features may be formed. In still other embodiments, higher precision and smaller minimum feature sizes may be desirable. In the present application, meso-scale and millimeter-scale have the same meaning and refer to devices that may have one or more dimensions that may extend into the 0.5-50 millimeter range, or somewhat larger, and features positioned with a precision in the micron to 100 micron range and with minimum feature sizes on the order of tens of microns to hundreds of microns.

The various embodiments, alternatives, and techniques disclosed herein may form multi-layer structures using a single patterning technique on all layers or using different patterning techniques on different layers. For example, various embodiments of the invention may perform selective patterning operations using conformable contact masks and masking operations (i.e. operations that use masks which are contacted to but not adhered to a substrate), proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), and/or adhered masks and masking operations (masks and operations that use masks that are adhered to a substrate onto which selective deposition or etching is to occur as opposed to only being contacted to it). Conformable contact masks, proximity masks, and non-conformable contact masks share the property that they are preformed and brought to, or in proximity to, a surface which is to be treated (i.e. the exposed portions of the surface are to be treated). These masks can generally be removed without damaging the mask or the surface that received treatment to which they were contacted or located in proximity to. Adhered masks are generally formed on the surface to be treated (i.e. the portion of that surface that is to be masked) and bonded to that surface such that they cannot be separated from that surface without being completely destroyed or damaged beyond any point of reuse. Adhered masks may be formed in a number of ways including (1) by application of a photoresist, selective exposure of the photoresist, and then development of the photoresist, (2) selective transfer of pre-patterned masking material, and/or (3) direct formation of masks from computer-controlled depositions of material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels (i.e. regions that lie within the top and bottom boundary levels that define a different layer's geometric configuration). Such use of selective etching and/or interlaced material deposition in association with multiple layers is described in U.S. patent application Ser. No. 10/434,519, by Smalley, filed May 7, 2019, which is now U.S. Pat. No. 7,252,86, and which is entitled “Methods of and Apparatus for Electrochemically Fabricating Structures Via Interlaced Layers or Via Selective Etching and Filling of Voids”. This referenced application is incorporated herein by reference.

Temporary substrates on which structures may be formed may be of the sacrificial-type (i.e. destroyed or damaged during separation of deposited materials to the extent they cannot be reused), non-sacrificial-type (i.e. not destroyed or excessively damaged, i.e. not damaged to the extent they may not be reused, e.g. with a sacrificial or release layer located between the substrate and the initial layers of a structure that is formed). Non-sacrificial substrates may be considered reusable, with little or no rework (e.g. replanarizing one or more selected surfaces or applying a release layer, and the like) though they may or may not be reused for a variety of reasons.

Definitions of various terms and concepts that may be used in understanding the embodiments of the invention (either for the devices themselves, certain methods for making the devices, or certain methods for using the devices) will be understood by those of skill in the art. Some such terms and concepts are discussed herein while other such terms are addressed in the various patent applications to which the present application claims priority and/or which are incorporated herein by reference.

### Enhanced Pin Probes:

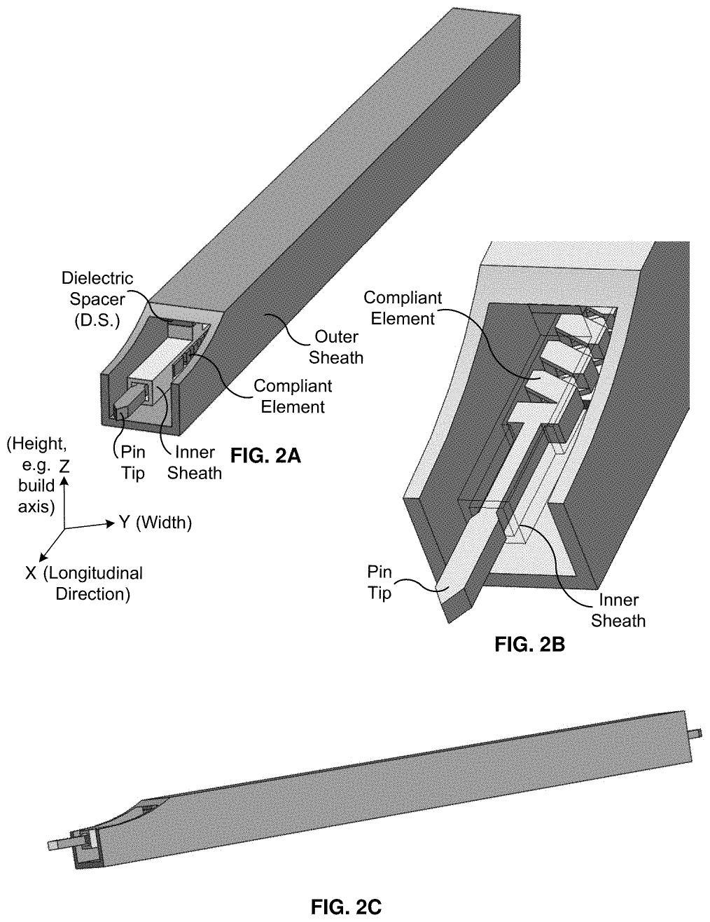

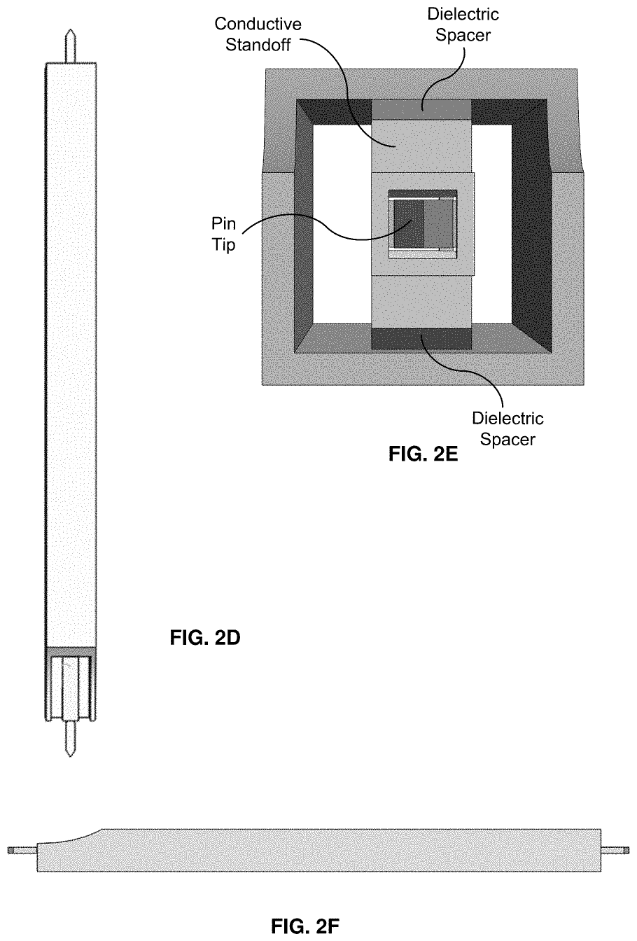

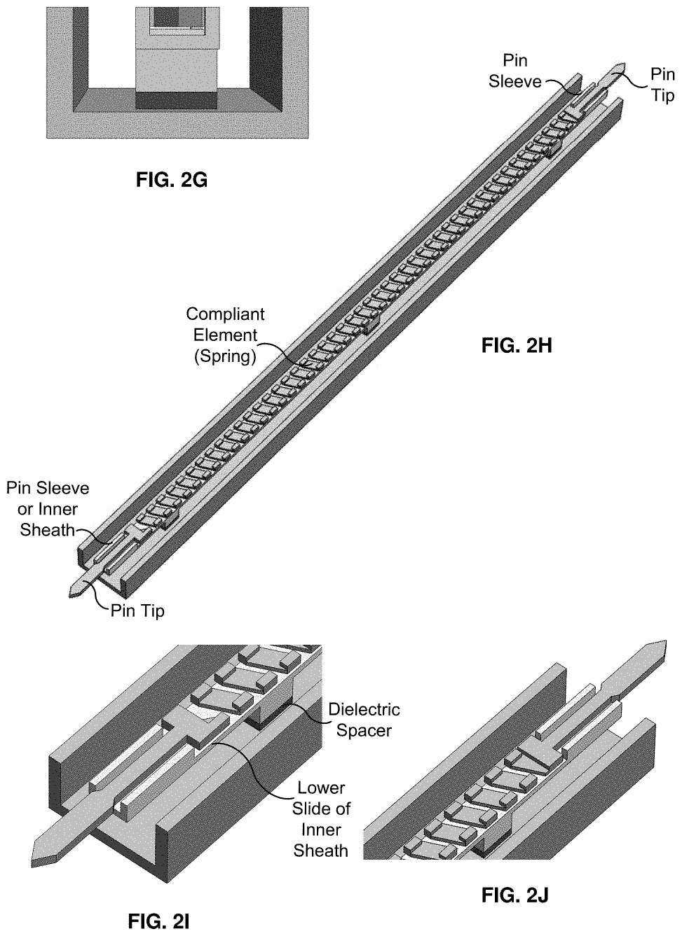

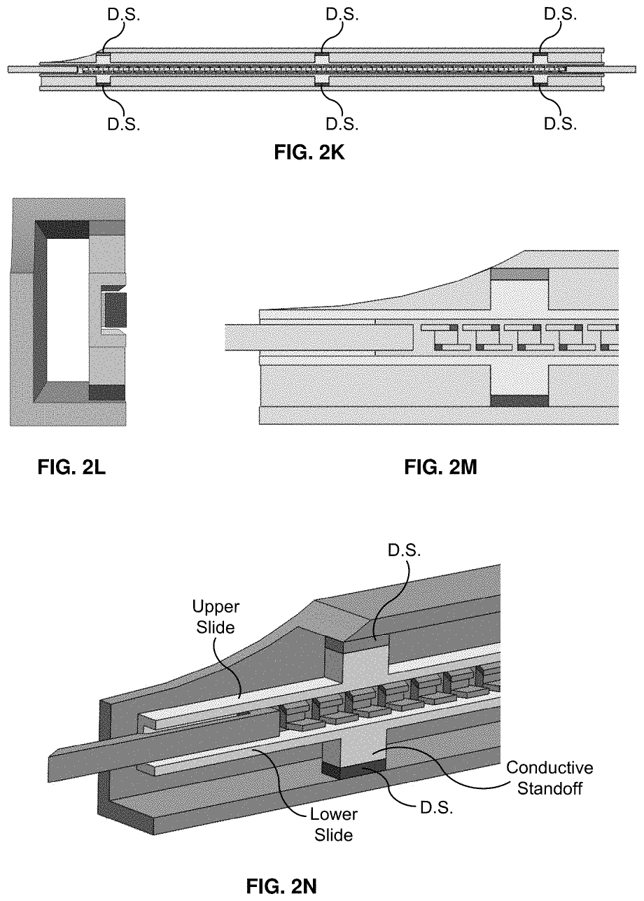

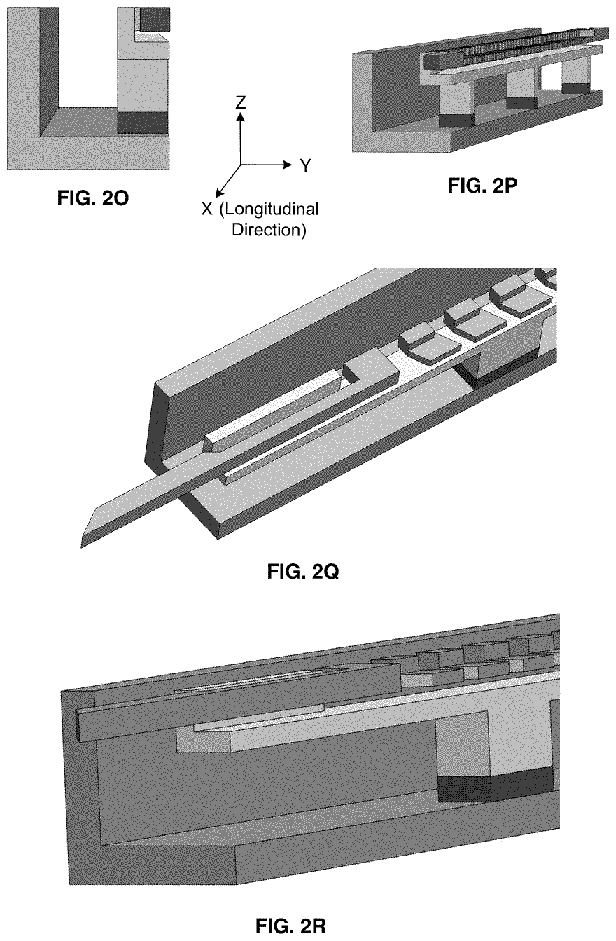

FIGS. 2A-2R provide various views of a sample coaxial pin-probe according to another embodiment wherein the pin probe includes a pin element that is compliantly biased by a rectangular coiled spring to move within a first sheath which is separated from a second surrounding sheath by dielectric spacers.

In this embodiment, a rectangular coaxial pin probe is provided with a pin element including two tips connected by a compliant intermediate section that includes a coiled, spiraling spring for compliantly biasing each pin outward from a conductive sheath having a top and bottom surface (but open sides) and having a stop feature on each end that inhibits either end of the pin element from over extension out of the first sheath. The first conductive sheath is in turn surrounded by, spaced from, and electrically isolated from a conductive second sheath which provides an outer shielding conductor spaced from the combined inner sheath and pin to provide a coaxial probe. Spacing and materials may be set to provide a desired impedance for the coaxial probe (e.g. 50 Hz or 75 Hz). In one embodiment, the moving pin tip can be made of, for example, palladium or rhodium. The spring may be made of, for example, nickel cobalt or palladium while the first sheath may be made of or coated with, for example, gold. The outer sheath may be formed of, for example, gold, palladium or nickel cobalt. The dielectric material separating the inner or first sheath from the second or outer sheath may be a deposited (e.g. spun on, sputtered, sprayed, spread or otherwise deposited) plastic or photoresist material (e.g. SU8, parylene, etc.) or it alternatively may be a ceramic or other dielectric material.

Though the dielectric may completely fill the void between the sheaths, it is preferred that it be locally positioned at a sufficient number of locations to ensure electrical isolation and position stability while sufficiently limited in usage to allow the vast majority of the space between the sheaths to be air filled. For example, the ends and central portions of the inner sheath may include an appropriate thickness, width, and length of dielectric to ensure stable position. In other embodiments, only the ends may include such a dielectric. In still other embodiments, the sides of the sheath near the ends and possibly at one or more intermediate locations may also include a dielectric. In some embodiments, an extension of metal and dielectric may occupy the distance between the sheaths while in other embodiments only a dielectric may occupy the space. When both metal and dielectric are used, the dielectric may be positioned at an outer surface of the inner sheath, at an inner surface of the outer sheath or at an intermediate position with a metal filling in gap. In some embodiments, the dielectric and/or the sheaths may have reentrant features that help ensure adhesion or locked joining of these elements. In some embodiments, the dielectric may only be positioned on one side of the sheath (e.g. only the bottom or only the top) while in other embodiments, the dielectric may be positioned along opposing sides of the sheaths or alternating positions from one side to the other at various positions along the length of the sheaths. In some embodiments, other cross-sectional configurations may be adopted by probes (e.g. square, rectangular, circular or stair-stepped circle-like, hexagonal, stair-stepped hexagonal, etc.). In some embodiments, the biasing spring may take on other configurations (e.g., S-shaped or stair-stepped serpentine, zig-zag, stacked buckled plates with or without spacers, the contact tips may take on other configurations, the length of the probe may vary, as may the thicknesses of walls, spring elements and the like. In some implementations, probes may have an overall width and height of any desired amount (e.g. 50-400 ums (microns)), a length of any desired amount (e.g. 0.5 mm to 5 mm), a sheath wall thickness of any desired amount which may be different between heights and widths and even vary along the length of the probe (e.g. 5-30 um), gaps of any desired amounts or that may be different in height and width and may vary along the length of the probe (e.g. 5-80 ums), spring member dimensions that may vary depending on spring type, spring length, parallel or series grouping of spring elements, type of material or coatings, required force, over travel requirements, and the like (e.g. 5-50 ums). In some embodiments, compliant members and tips may be formed separately from sheaths and sheaths may be formed separately from one another but to minimize assembly costs, all probe elements may be formed to together in a single fabrication process. In some embodiments, probe tips may extend from the inner sheath for formation purposes and to allow a desired level of spring bias (via desired displacement) over the entire working range of tip displacement. In some embodiments, multiple inner sheaths may exist within the same outer sheath or without an intermediate isolating outer sheath extension located between the inner sheaths. In some embodiments, the second movable contact tip may be replaced by a fixed contact tip. The probes may be used in various applications such as wafer test or package test, burn-in or the like, at various pitch spacings (e.g. 75-500 microns, e.g. 100-200 microns, e.g. 120-180 microns). Other alternatives are also possible and include the features of other embodiments set forth herein and the various alternatives to those other embodiments.

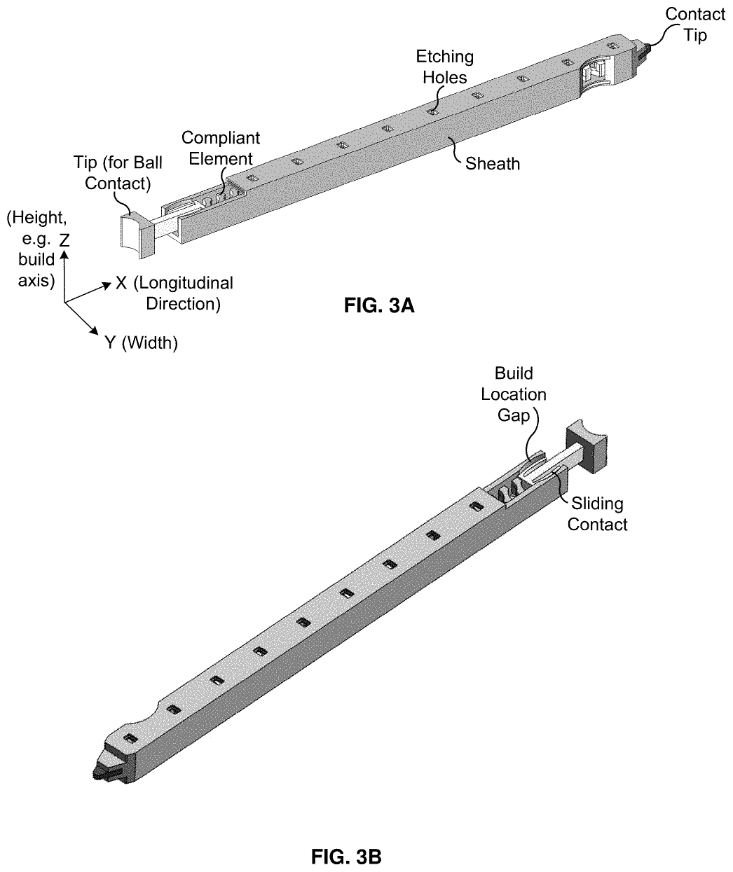

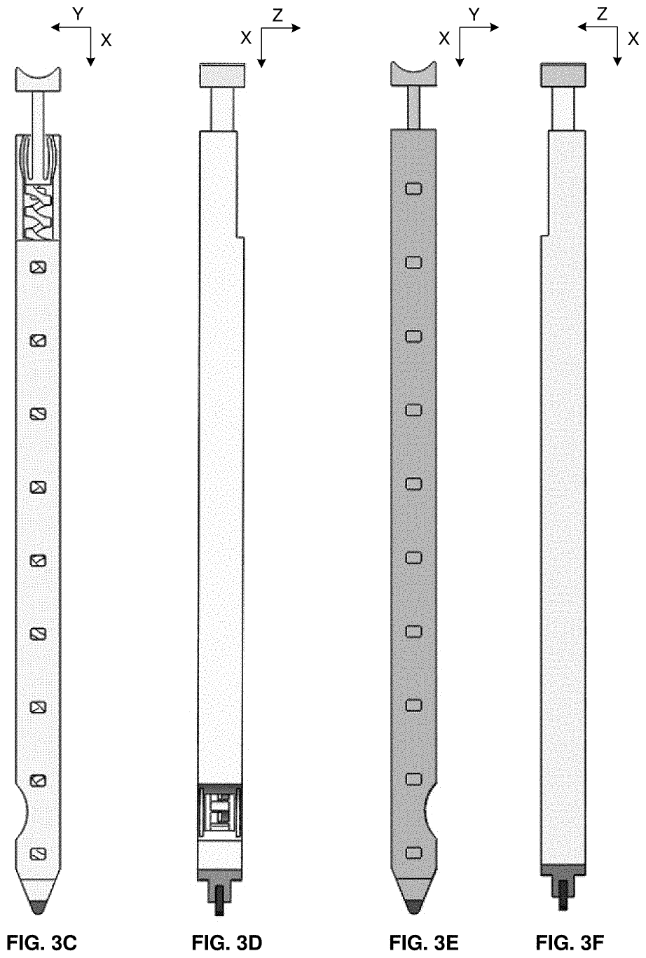

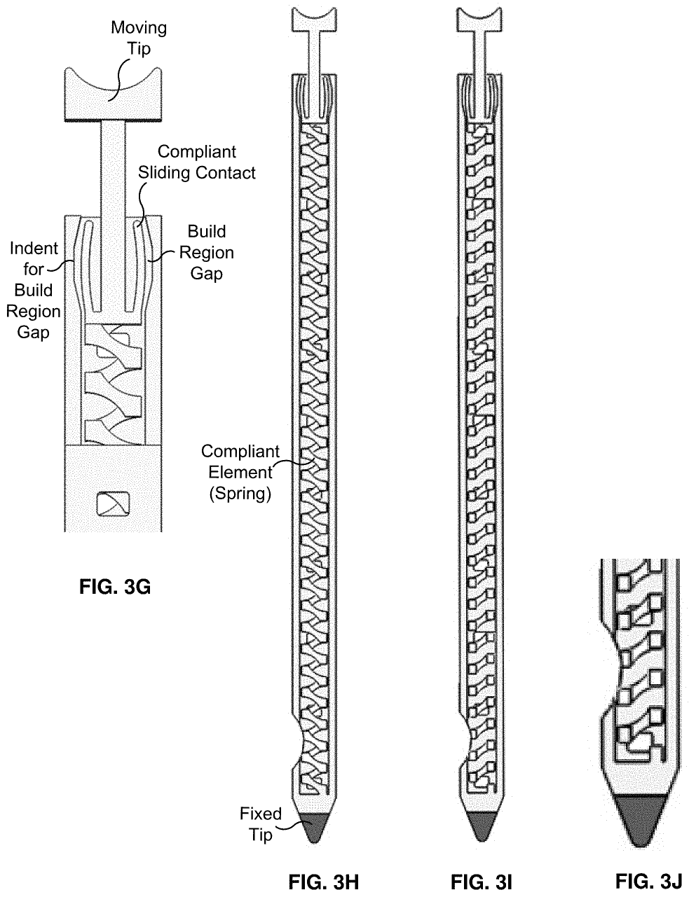

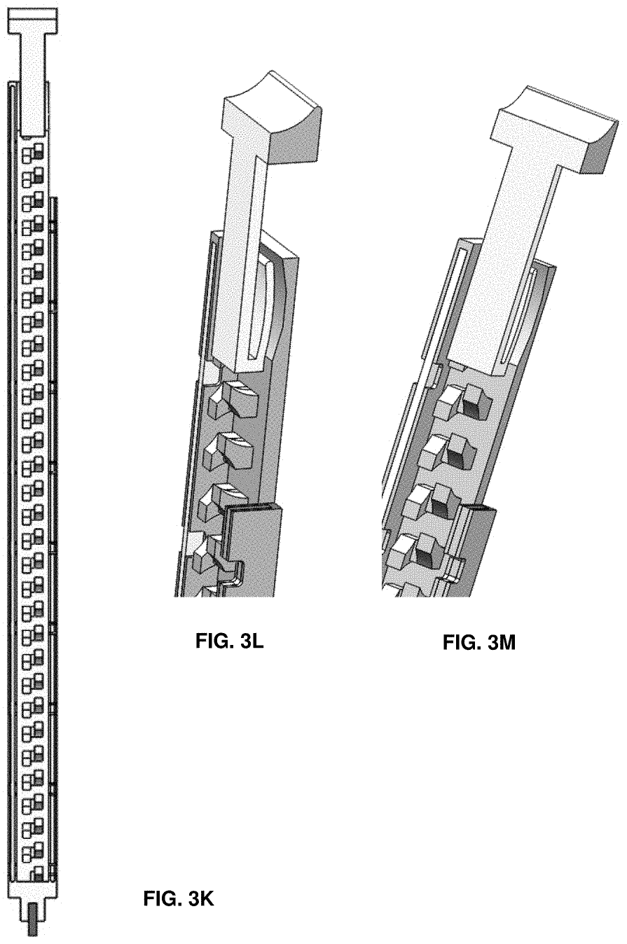

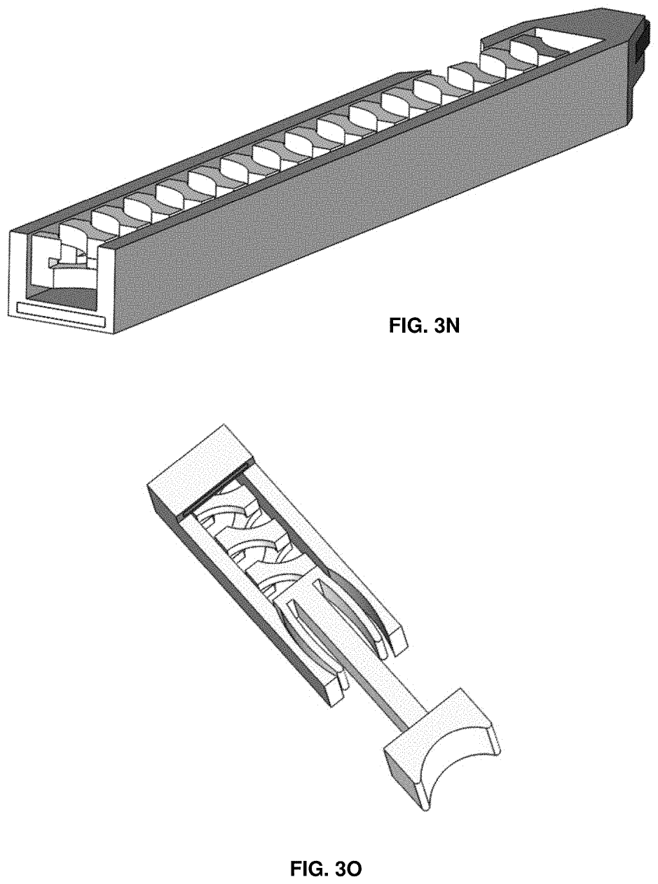

FIGS. 3A-3O provide various views of a sample pin probe including a pin element and a sheath that can shunt current from a moveable pin element to a sheath and then to a fixed tip. The shunting may occur at or near the movable tip of the pin element. In this embodiment, the probe is provided with a movable tip structure located at an end of a rectangular spiral compliant biasing member and a fixed tip at the other end of the biasing member. In this embodiment, the tip has the shape of a cylindrical, elliptical, or other concave section and may be useful for engaging solder bumps or other nonplanar contacts. The moving tip, or a separate feature of the pin element near the moving tip, provides a spring loaded slidable contact element for contacting the inside surface of a surrounding sheath once the compliant element is compressed from a build length (where opposing features are spaced from one another by gaps that are adequate to ensure that minimum feature size tolerances are met) to a working range (where the tip can still move with ease while providing axial compliance over an adequate over travel length, and while making electrical contact to form a reliable, radial direction spring bias, and shortened path from the moving tip to the fixed tip where the path includes a substantial length of the sheath. In some variations of this embodiment, including the example depicted, the sheath or other portions of the probe may be made with core material surrounded completely or substantially by shell material (e.g. copper cores surrounded by palladium, gold or nickel cobalt shells) to improve conductivity and current carrying capacity. In some variations (like the present embodiment), the side contact biasing elements (radial biasing elements) may be part of the moving pin element, and they may contact and be biased against the inner side walls of the sheath while in a working range of motion, while in other embodiments they may be in contact with the floor and or ceiling of the sheath. In still other embodiments, the biased conductive elements may not be part of the moving pin element but instead may be part of the sheath such that they extend inward to contact a portion of the axial compliant biasing member, moving tip or other part of the pin element. In some alternative embodiments, moving tips may exist on each end of the probe. In other embodiments, other tip shapes are possible. In some embodiments, a concave tip may be provided with some compliance to allow some degree of tilting if a solder bump or the like is contacted off center. In some embodiments, the probe dimensions may be similar to those noted in the example of FIGS. 2A-2P while in others, the probe may be even smaller when no second sheath is used. In some embodiments, for example, a 2 mm probe may be required to handle 200 um of overtravel. Though some embodiments may require some assembly of probe components, and other embodiments may require movement of pin elements from fabrication positions to working locations, some embodiments may require no post layer fabrication assembly at all. Other alternatives are also possible and include the features of other embodiments set forth herein and the various alternatives to those other embodiments.

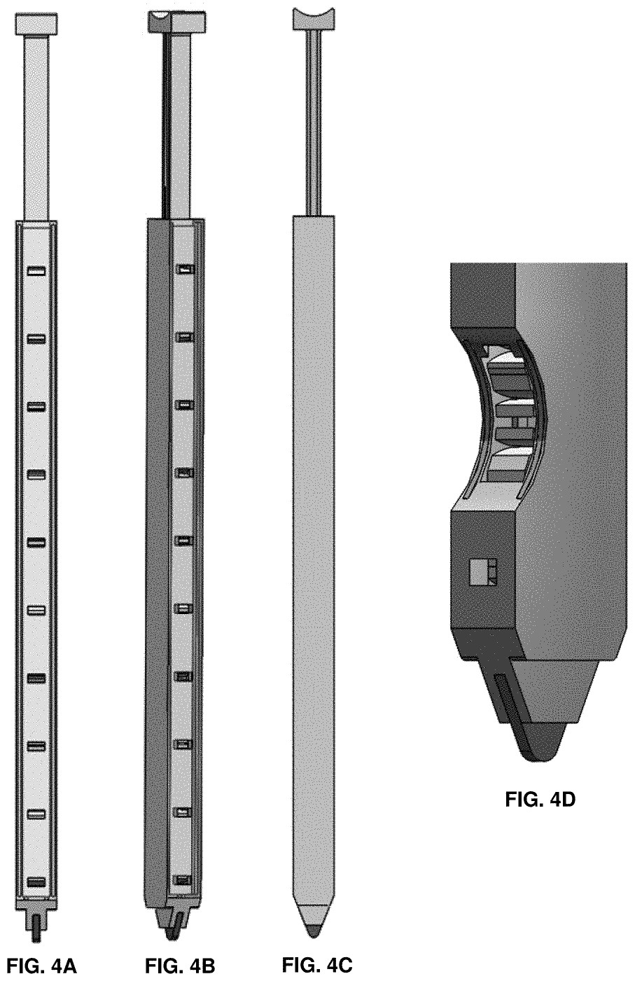

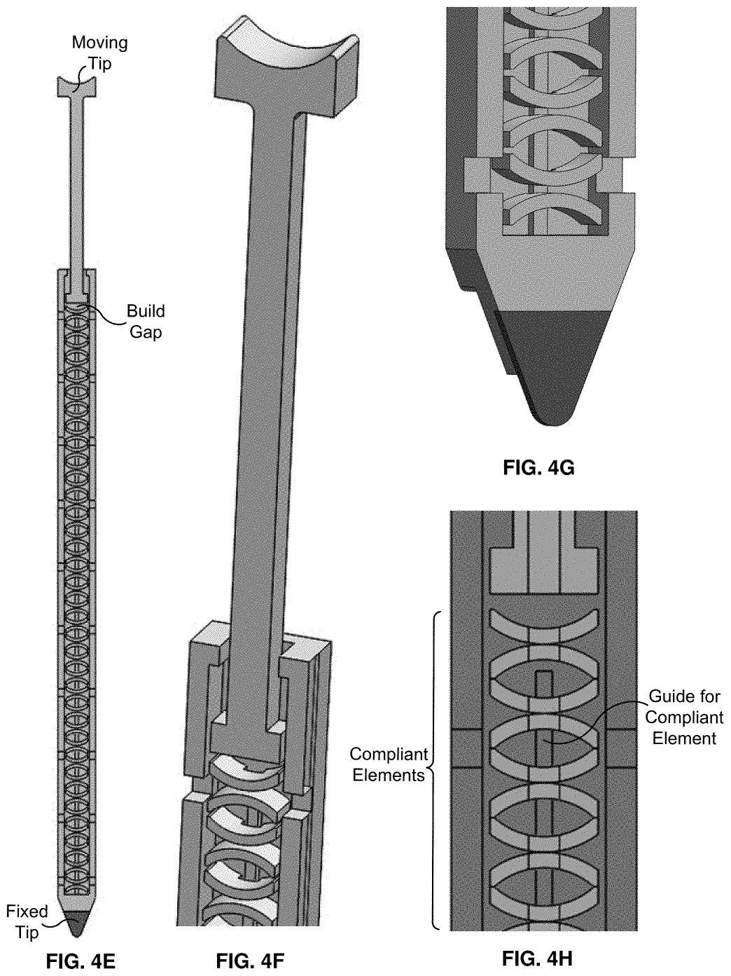

FIGS. 4A-4H provide various views of another sample pin probe with a single moving tip and fixed tip with an alternative spring configuration wherein the spring is comprised of a plurality of attached or separate but stacked curved or non-planar plates or disks that can be compressed to become more planar while supplying a spring force.

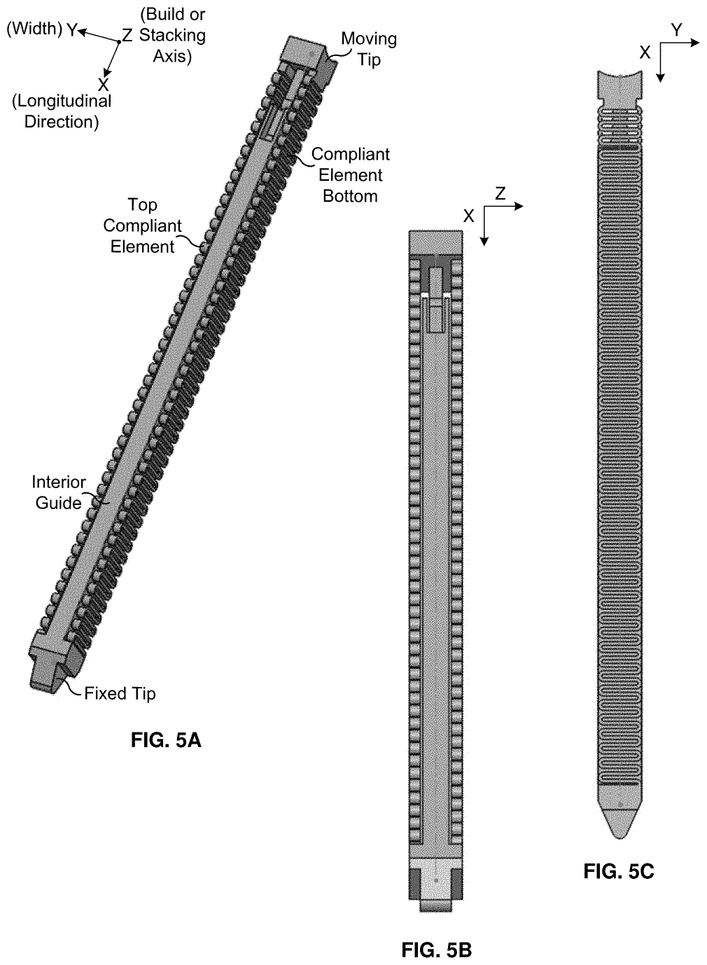

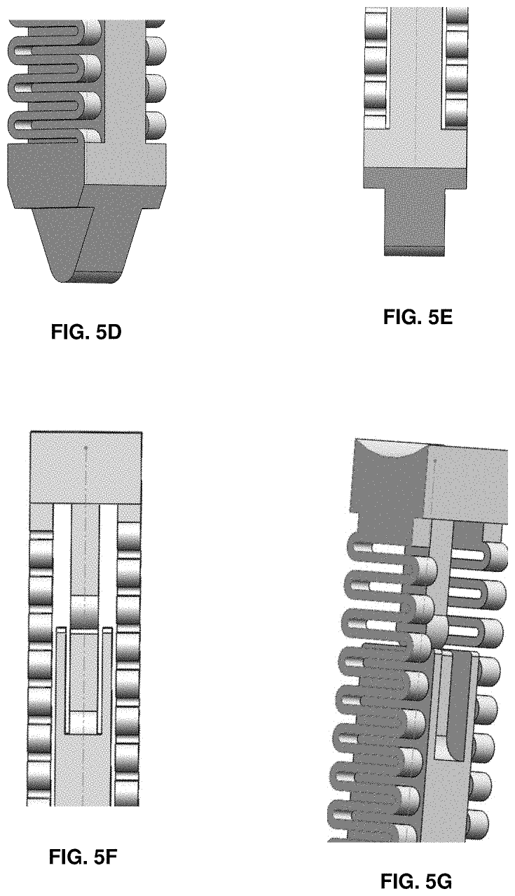

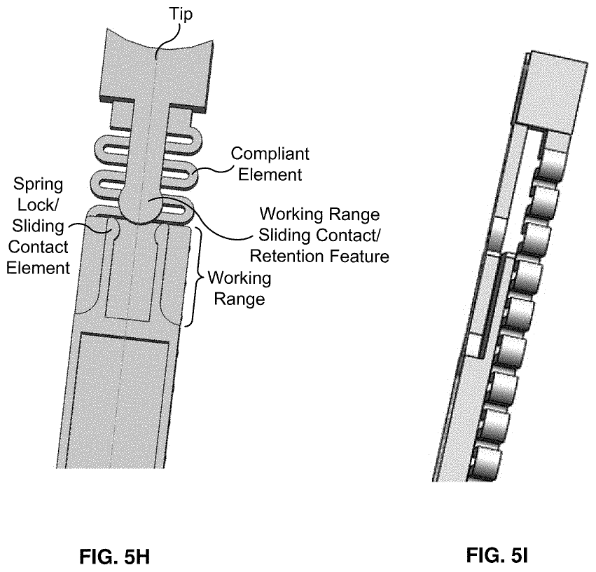

FIGS. 5A-5I provides another sample pin probe with a single moving tip and a fixed tip with another alternative spring configuration that includes a fabrication position that is different from a working range wherein the moving pin moves from the fabrication position to a use position via movement past a compliant engagement element that allows a feature that moves with the tip to slide past it during compression while inhibiting movement back over the feature in the presence of a return force provided by the biasing spring such that the moving pin element remains in the working range and does not return, under normal working conditions, to the fabrication position. In this embodiment, the spring does not move inside a sheath but instead is located externally to a rigid guide element. In some alternative embodiments, it may be useful to change out the serpentine biasing spring elements of the present embodiment for a spiral spring or a spring that include elements that attach the two axial biasing springs to one another (e.g. via an element extending through a slot in the rigid guide member, or elements that extend around the guide member to help ensure that the moving spring does not buckle outward and short against a neighboring probe). Numerous other alternatives to the present embodiment exist and may include the features of other embodiments set forth herein and the various alternatives to those other embodiments.

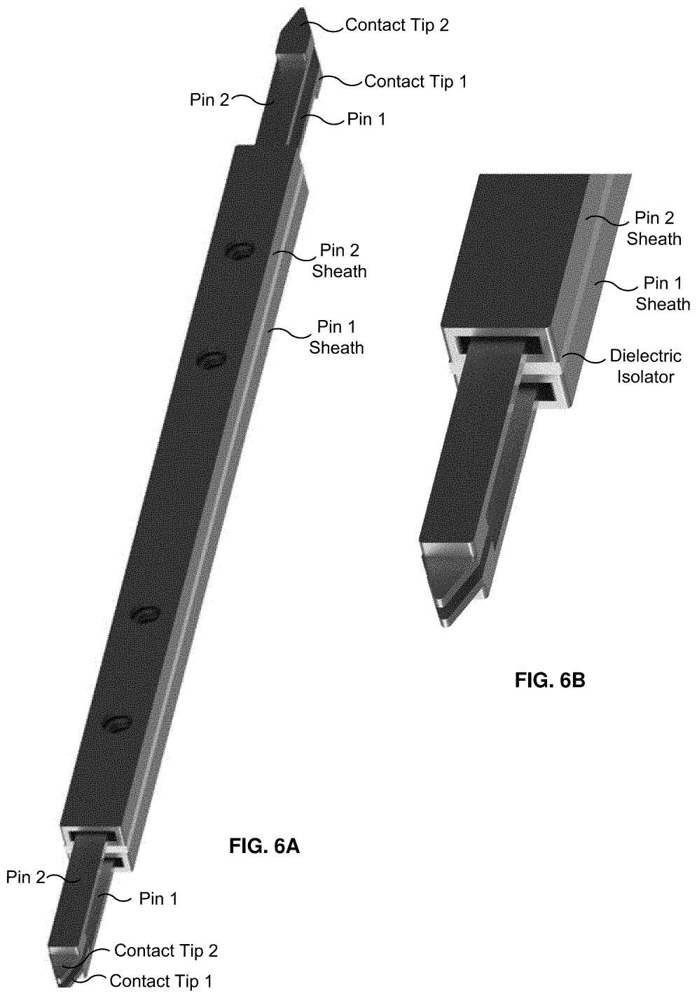

FIGS. 6A-6B provide another sample pin probe including a pair of electrically isolated probes that include moving tips on one side and fixed tips on the other wherein the moving tips are rigidly joined for coincident movement but decoupled sufficiently to allow for pad non-uniformities and wherein the tips are electrically isolated from one another by a dielectric barrier located between the pair or at least spacing members of the pair from each other. Probes of this type and variations thereof may be used for fine pitch Kelvin testing of substrates and probe packages. Probes of this embodiment may have similar sizes and pitches to the example probes of FIGS. 2A-5H. Numerous other alternatives to the present embodiment exist and may include the features of other embodiments set forth herein and the various alternatives to those other embodiments.

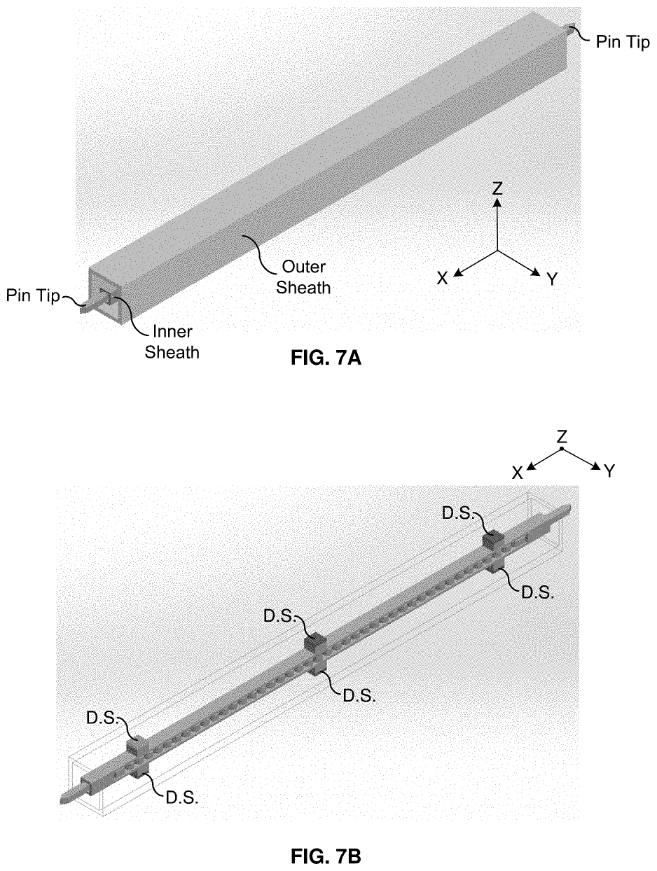

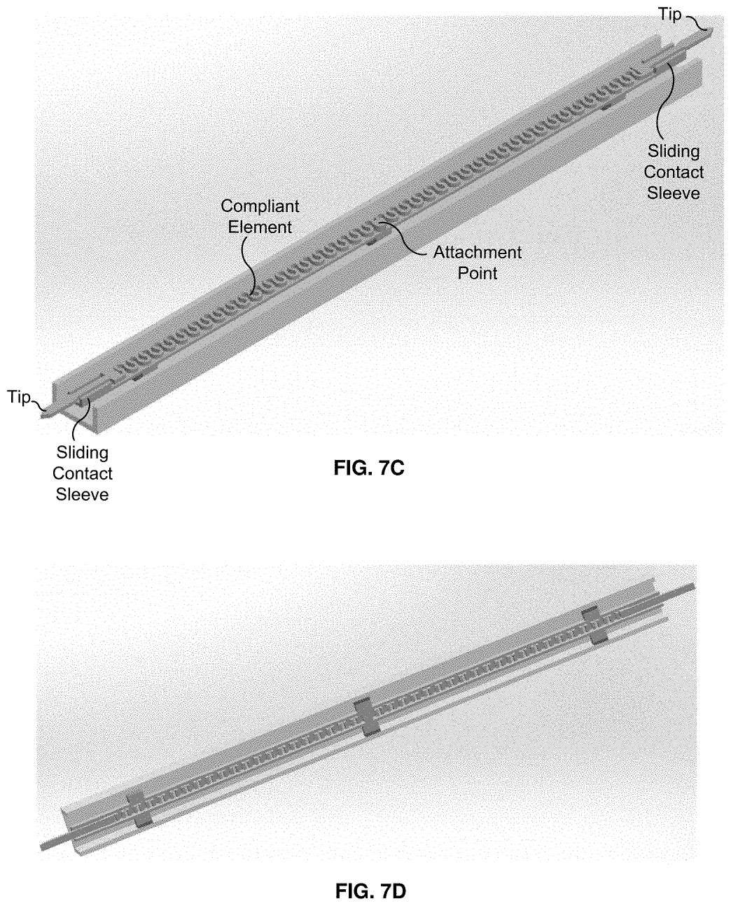

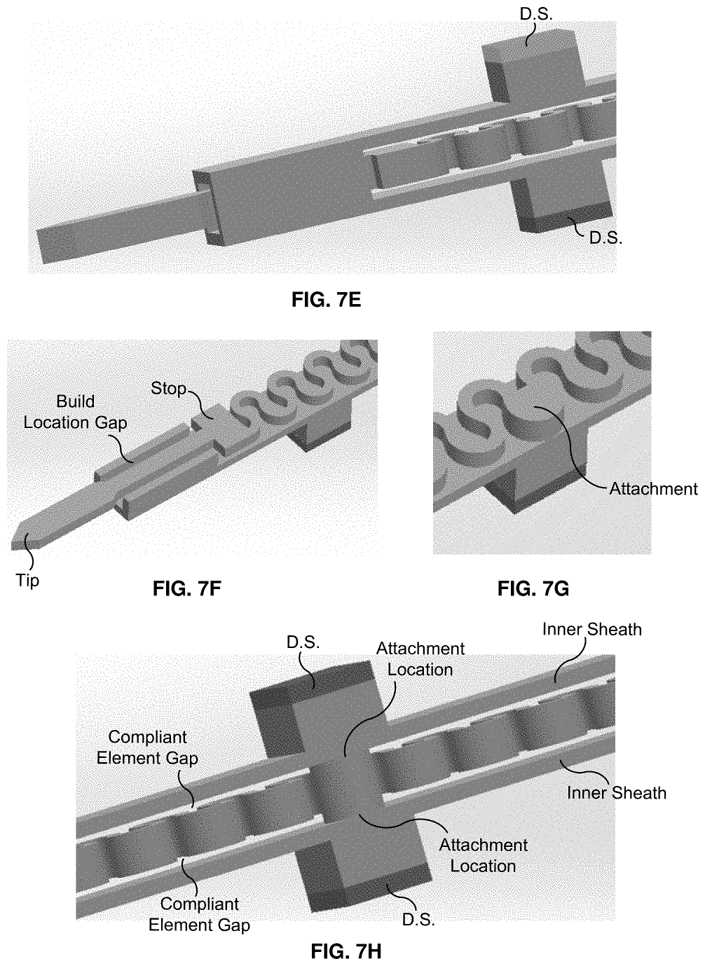

FIGS. 7A-7H provide various views of a shielded pseudo coaxial probe according to another embodiment of the invention that includes a central conductor and a fixed length shielding conductor wherein the central conductor includes lower and upper fixed length surfaces connected to the shield conductor by dielectric spacers (e.g. at each end and at an intermediate location) and which are joined to one another at each end via side wall elements through which a passage extends and are spaced from one another by a gap in a central region in which a meandering spring is compressibly located, connected at an intermediate location to the lower and upper surfaces, and connected to contact tip elements on either end that extend through the passages and that include stop elements that keep the contact tip elements from extending too far out of the shield element via an interaction between the stop elements and the passage side walls when the tips are not contacting surfaces to be electrically connected and the spring is not under a compressive load. Numerous variations of this embodiment are possible and include the variations and features associated with other embodiments set forth herein. Such variations may include, forgoing the connection of the spring to either of the surfaces in favor of one or more sliding elements that are attached to either side of the spring and that can slide along the edge of the top and/or bottom surfaces to ensure that the spring stays located between the surfaces wherein such catch elements may provide additional periodic conductive paths between the spring and the surfaces for carrying current and improving RF properties of the probe. In some embodiments, regions of the surfaces and the slides themselves may be formed of a high wear, good electrical contact material (e.g. rhodium) to improve contact/conductive probe performance or to extend wear life of the probes.

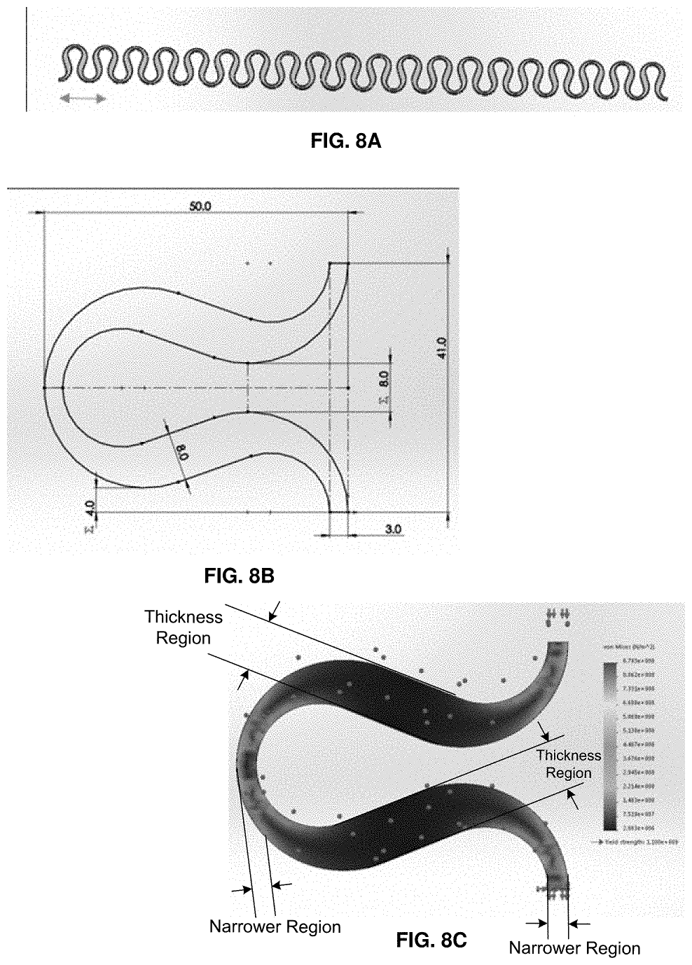

FIGS. 8A-8C depict a spring comprising a plurality of S-shaped segments (FIG. 8A) that may be used in various embodiments of the invention wherein the each S-shaped segment (FIG. 8B), or at least selected S-Shaped segments, are configured to have widths of varying dimensions (some narrower regions and some wider regions) that may be designed and formed to optimize performance of the spring such as stress loading as shown in the stress simulation image of FIG. 8C or to optimize other parameters singly or in combinations (e.g. length, spring constant, over travel, stress loading, current carrying capacity, and the like). Modifications to the structure of this embodiment are possible and may include, for example, additional spring elements located in parallel or in series, segments taking on configurations other than S-shapes, configurations that vary over the length of the spring, and the like.

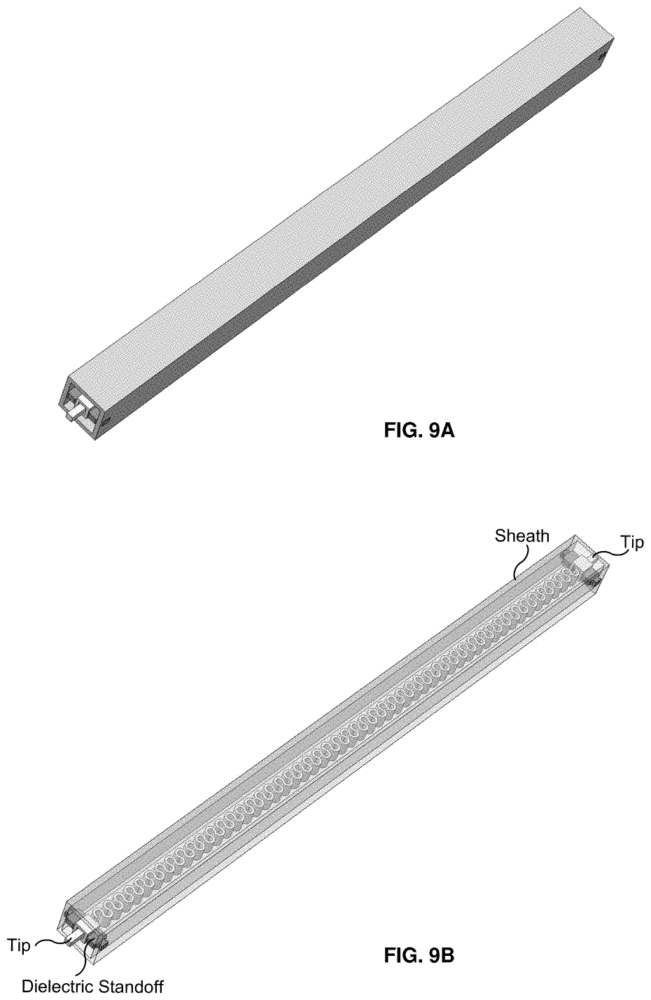

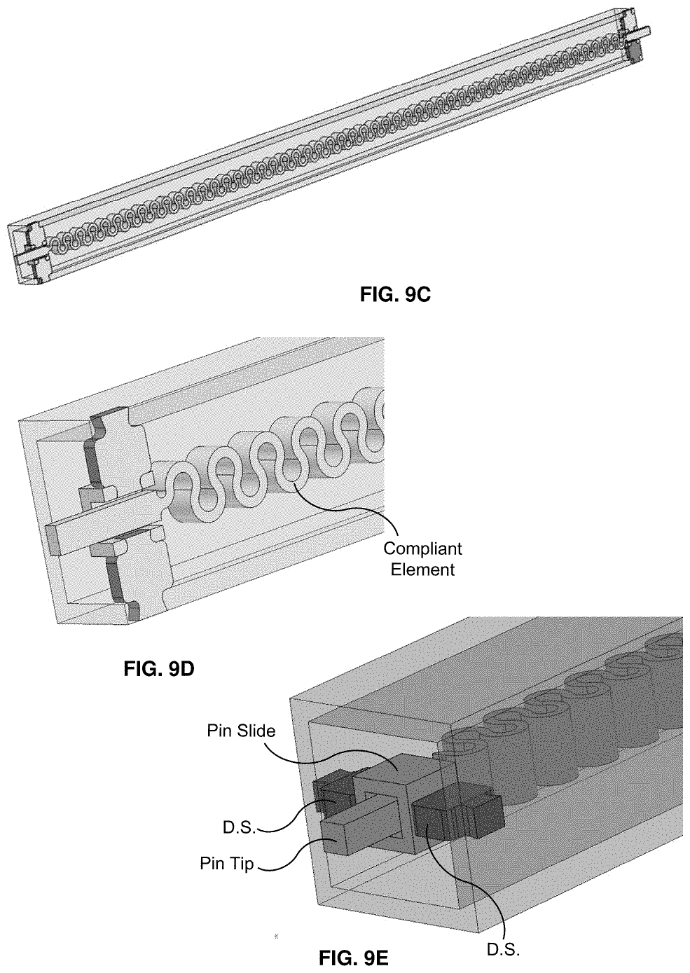

FIGS. 9A-9E provide various views of a shielded pseudo coaxial probe of another embodiment of the invention, similar in some respects to that of FIGS. 7A-7H with the notable exception that the upper and lower surfaces of the central conductor are removed in favor of using the spring as the central conductor wherein the central conductor is retained at each end by rectangular structures with central passages where the rectangular structures are held in position relative to the outer conductive shield by dielectric spacers that may engage the shield as well as the rectangular structures with reentrant features or simply features of varying width along a radial length of the dielectric so as to lock the rectangular structures, the shield and the dielectric itself together mechanically thus reducing the need for bonding strength alone to hold adjacent elements or structures in place. As with the other embodiments, numerous variations are possible and include, for example, inclusion of one or more intermediate fixtures for slidably holding the spring along the central axis or other desired longitudinal line along the length of the shield. In other embodiments, a mount (e.g. a dielectric mount) may be located between the two ends of the probe so as to fix a desired point along the length of the spring to a desired location within the outer shield. In other embodiments, the spring may include one or more non-compressible or non-compliant regions.

FIGS. 10A-10D provide another example pseudo coaxial probe but where only one end has significant compliance. The central conductor in this embodiment, over the majority of the length of the probe, has a substantially incompressible, rigid bar that is attached to a compressible spring near the compliant contact tip via a dielectric spacer and where the movable contact tip is fixed radially relative to the shield by a sliding rectangular loop that in turn connects to the outer shield by dielectric spacers. The opposite end of the bar engages a substantially fixed contact element (held and electrically isolated from the shield by mounts that include dielectric spacers) which the bar can slide against as the spring compresses. The opposite end of spring is attached to the outer shield. The sliding contact allows controllable contact and movement of the bar under compressive force or under restorative spring force. As with the other embodiments, numerous alternatives are possible and include for example inclusion of spring capture, or retention, elements or structures that hold the spring to desired radially locations relative to the outer shield. In other embodiments, the spring may be fixed to the central conductor without a dielectric, and a dielectric may be used to isolated an opposite end of the spring from the outer shield. In some embodiments, the spring maybe formed with dielectric elements that inhibit contact of the spring to surfaces too which shorting is to be avoided.

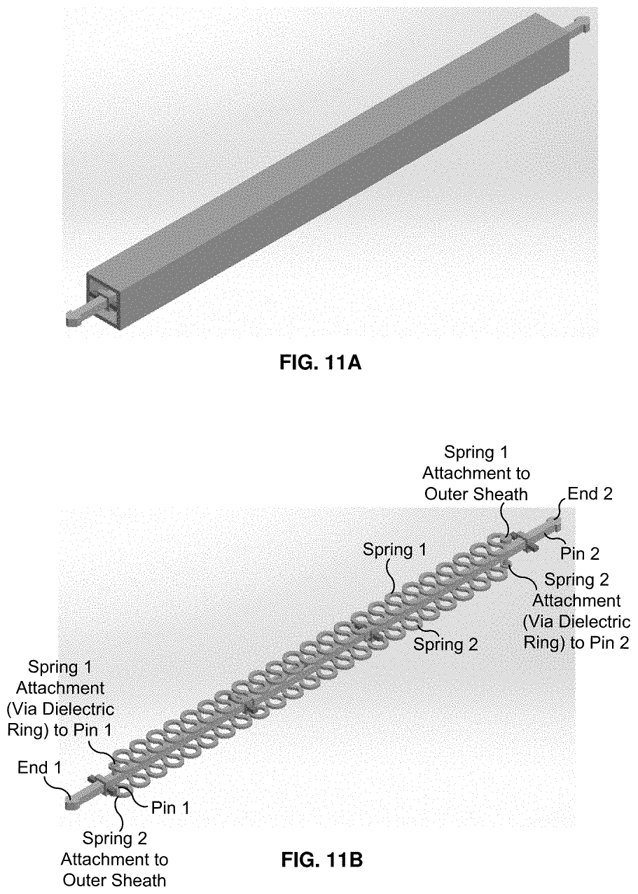

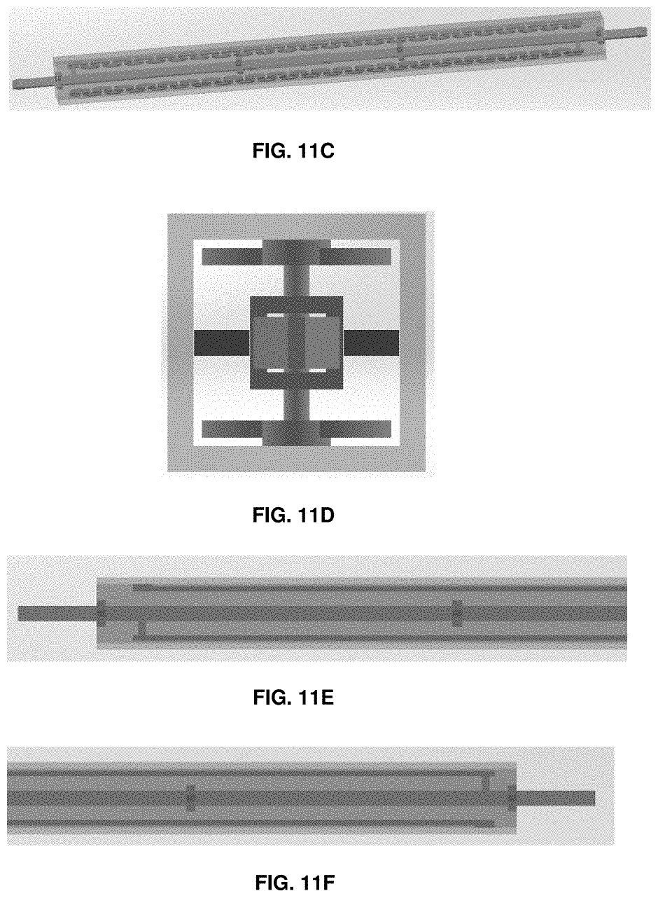

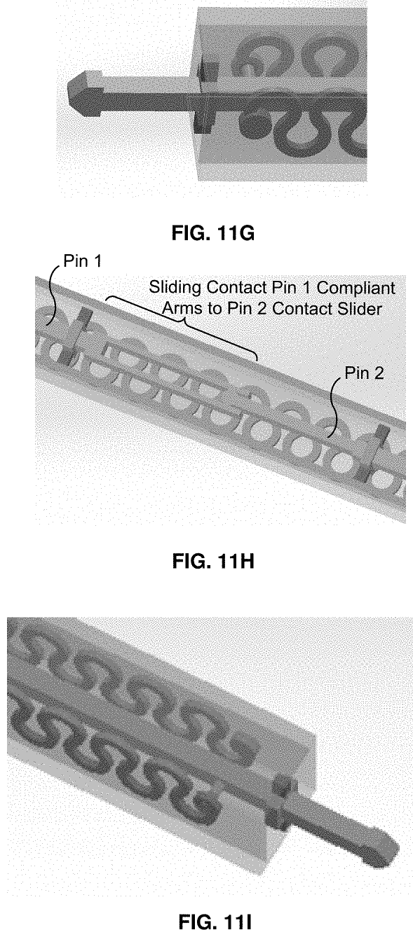

FIGS. 11A-11I provide various views of an embodiment similar to that of FIGS. 10A-10D with the primary exception being that the probe has two compliant contact elements and the sliding contact elements of the central conductive bar are located more centrally along the longitudinal length of the probe and as with the embodiment of FIGS. 10A-10D, the probe is provided with a pair of compressible springs with one located below and the other above the central conductor and inside the outer shield. As with the other embodiments, numerous variations are possible and include moving the springs to the outside of the shielding conductor via radially extending arms that connect the springs to a point on the central conductor(s) via a dielectric interface and connect the opposite end of the spring to the outer shielding conductor where the radially extending arms may be located in a slot in the outer conductor of adequate length and position to allow the contact end, or ends, of the probe to undergo required overtravel when making contact to electrical components.

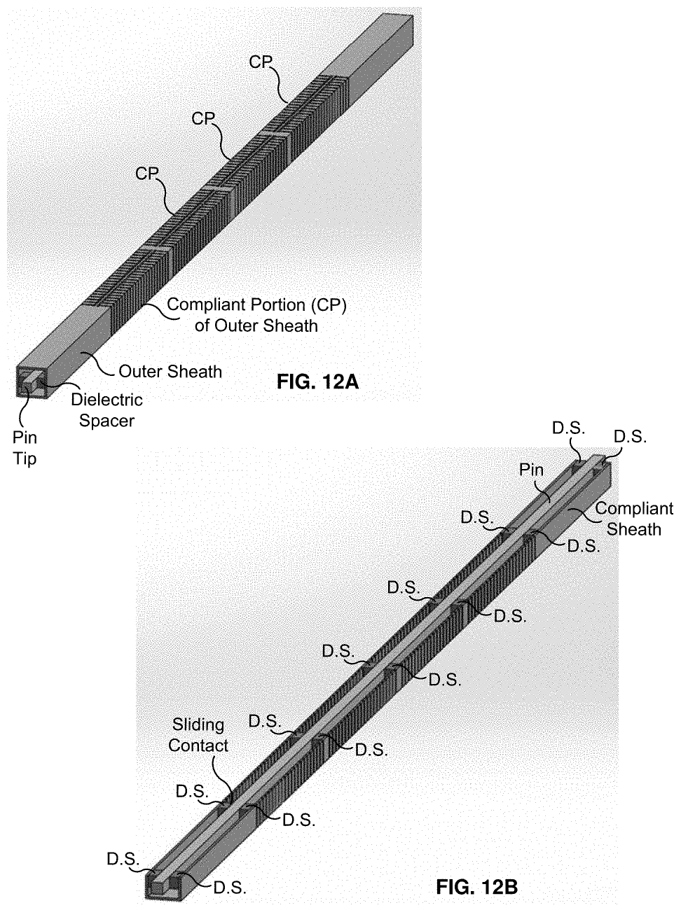

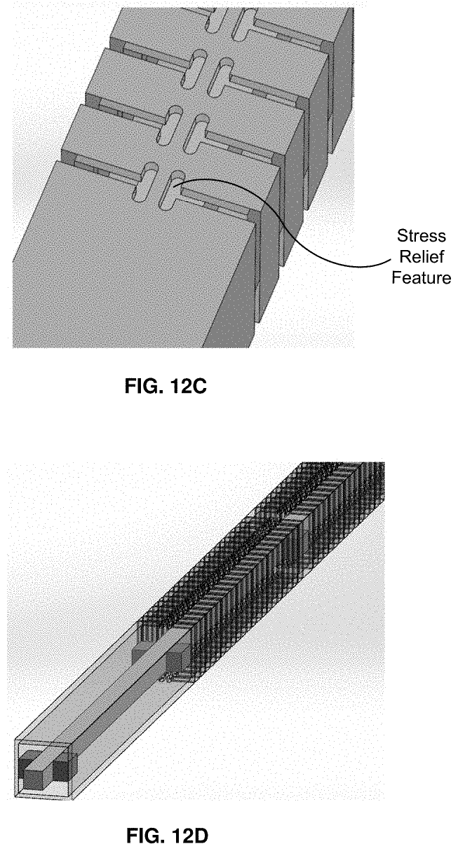

FIGS. 12A-12D provide various views of a pseudo coaxial probe that includes a relatively incompressible central conductor that can elastically bend or buckle which is located within a cage-like outer shielding conductor, and is spaced from the outer conductor by dielectric elements that are attached to the central or to the outer conductor where the outer conductor includes features that allow compliance along one axis that is substantially perpendicular to a local longitudinal axis of the probe but not along the other axis which is locally perpendicular to both. Various alternatives to the present embodiment exist and include, for example, the central conductor also including features that preferentially enable compliance along a first axis and inhibit compliance along another axis that is perpendicular to the first axis and to a local longitudinal axis of the probe.

In still other embodiments, sheathed pin probe structures may provide a compliant tip at only one end of a sheath while electrical contact to a non-compliant end may be made by solder bonding, wire bonding, diffusion bonding, ultrasonic welding, brazing, or the like. Alternatively bonding to the noncompliant end may simply occur as a result of pressure from mating the compliant end to a contact location. In some embodiments, particularly where sliding of elements, or structures, against one another may occur, the structure may be formed with regions of a wear resistant and/or good electrical contact material (e.g. rhodium) to improve reliability of electrical contact and/or wear life of the probe. In such cases, it may be desirable to form the contact region, in any given sliding location, from a single layer that includes protrusions on each side of the contact, relative to the layers above and below to ensure that any layer-to-layer positions variations (e.g. due to offset tolerances) do not impact performance.

Still other embodiments may be created by combining the various embodiments and their alternatives which have been set forth herein with other embodiments and their alternatives which have been set forth herein.

### Further Comments and Conclusions

Various other embodiments of the present invention exist. Some of these embodiments may be based on a combination of the teachings herein with various teachings incorporated herein by reference. For example, some embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, molybdenum, manganese, brass, chrome, chromium copper (Cr—Cu), and combinations of these. Some embodiments may use copper as the structural material with or without a sacrificial material.

Structural or sacrificial dielectric materials may be incorporated into embodiments of the present invention in a variety of different ways. Such materials may form a third material or higher deposited on selected layers or may form one of the first two materials deposited on some layers. Additional teachings concerning the formation of structures on dielectric substrates and/or the formation of structures that incorporate dielectric materials into the formation process and possibility into the final structures as formed are set forth in a number of patent applications filed Dec. 31, 2003: (1) U.S. Patent Application No. 60/534,184 which is entitled “Electrochemical Fabrication Methods Incorporating Dielectric Materials and/or Using Dielectric Substrates”; (2) U.S. Patent Application No. 60/533,932, which is entitled “Electrochemical Fabrication Methods Using Dielectric Substrates”; (3) U.S. Patent Application No. 60/534,157, which is entitled “Electrochemical Fabrication Methods Incorporating Dielectric Materials”; (4) U.S. Patent Application No. 60/533,891, which is entitled “Methods for Electrochemically Fabricating Structures Incorporating Dielectric Sheets and/or Seed layers That Are Partially Removed Via Planarization”; and (5) U.S. Patent Application No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into the EFAB process include (1) U.S. patent application Ser. No. 11/139,262, filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216, filed Jan. 3, 2005 by Cohen, et al., now abandoned, and which is entitled “Electrochemical Fabrication Methods Incorporating Dielectric Materials and/or Using Dielectric Substrates”. (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (5) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (6) U.S. patent application Ser. No. 10/607,931, by Brown, et al., which was filed on Jun. 27, 2003, now U.S. Pat. No. 7,239,219, and which is entitled “Miniature RF and Microwave Components and Methods for Fabricating Such Components”, (7) U.S. patent application Ser. No. 10/841,006, by Thompson, et al., which was filed on May 7, 2004, now abandoned, and which is entitled “Electrochemically Fabricated Structures Having Dielectric or Active Bases and Methods of and Apparatus for Producing Such Structures”; (8) U.S. patent application Ser. No. 10/434,295, by Cohen, which was filed on May 7, 2003, now abandoned, and which is entitled “Method of and Apparatus for Forming Three-Dimensional Structures Integral With Semiconductor Based Circuitry”; and (9) U.S. patent application Ser. No. 10/677,556, by Cohen, et al., filed Oct. 1, 2003, now abandoned, and which is entitled “Monolithic Structures Including Alignment and/or Retention Fixtures for Accepting Components”.

These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,384 which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full.

A. U.S. patent application Ser. No. 10/271,574, filed on Oct. 15, 2002, issued as U.S. Pat. No. 7,288,178 on Oct. 30, 2007, and entitled “Methods of and Apparatus for Making High Aspect Ratio Microelectromechanical Structures” by Cohen
B. U.S. patent application Ser. No. 10/387,958, filed on Mar. 13, 2003, published as US App Pub No. 2003-022168 on Dec. 4, 2003, and entitled “Electrochemical Fabrication Method and Application for Producing Three-Dimensional Structures Having Improved Surface Finish” by Cohen
C. U.S. patent application Ser. No. 10/434,289, filed on May 7, 2003, published as US App Pub No. 2004-0065555 on Apr. 8, 2004 and entitled “Conformable Contact Masking Methods and Apparatus Utilizing In Situ Cathodic Activation of a Substrate” by Zhang
D. U.S. patent application Ser. No. 10/434,294, filed on May 7, 2003, published as US App Pub No. 2004-0065550 on Apr. 8, 2004 and entitled “Electrochemical Fabrication Methods With Enhanced Post Deposition Processing” by Zhang
E. U.S. patent application Ser. No. 10/434,315, filed on May 7, 2003, issued as U.S. Pat. No. 7,229,542 on Jun. 12, 2007, and entitled “Methods of and Apparatus for Molding Structures Using Sacrificial Metal Patterns” by Bang
F. U.S. patent application Ser. No. 10/434,494, filed on May 7, 2003, published as US Pub App No. 2004-0000489 on Jan. 1, 2004, and entitled “Methods and Apparatus for Monitoring Deposition Quality During Conformable Contact Mask Plating Operations” by Zhang
G. U.S. patent application Ser. No. 10/677,498, filed on Oct. 1, 2003, issued as U.S. Pat. No. 7,235,166 on Jun. 26, 2007, and entitled “Multi-cell Masks and Methods and Apparatus for Using Such Masks To Form Three-Dimensional Structures” by Cohen
H. U.S. patent application Ser. No. 10/697,597, filed on Dec. 20, 2002, published as US Pub App No. 2004-0146650 on Jul. 29, 2004, and entitled “EFAB Methods and Apparatus Including Spray Metal or Powder Coating Processes” by Lockard
I. U.S. patent application Ser. No. 10/724,513, filed on Nov. 26, 2003, issued as U.S. Pat. No. 7,368,044 on May 6, 2008, and entitled “Non-Conformable Masks and Methods and Apparatus for Forming Three-Dimensional Structures” by Cohen
J. U.S. patent application Ser. No. 10/724,515, filed on Nov. 26, 2003, issued as U.S. Pat. No. 7,291,254 on Nov. 6, 2007, and entitled “Method for Electrochemically Forming Structures Including Non-Parallel Mating of Contact Masks and Substrates” by Cohen
K. U.S. patent application Ser. No. 10/830,262 on Apr. 21, 2004, issued as U.S. Pat. No. 7,198,704 on Apr. 3, 2007, and entitled “Methods of Reducing Interlayer Discontinuities in Electrochemically Fabricated Three-Dimensional Structures” by Cohen
L. U.S. patent application Ser. No. 10/841,100, filed on May 7, 2004, issued as U.S. Pat. No. 7,109,118 on Sep. 19, 2006, and entitled “Electrochemical Fabrication Methods Including Use of Surface Treatments to Reduce Overplating and/or Planarization During Formation of Multi-layer Three-Dimensional Structures” by Cohen
M. U.S. patent application Ser. No. 10/841,347, filed on May 7, 2004, published as US Pub App No. 2005-0072681 on Apr. 7, 2005, and entitled “Multi-step Release Method for Electrochemically Fabricated Structures” by Cohen
N. U.S. patent application Ser. No. 10/949,744, filed on Sep. 24, 2004, issued as U.S. Pat. No. 7,498,714 on Mar. 3, 2009, and entitled “Multi-Layer Three-Dimensional Structures Having Features Smaller Than a Minimum Feature Size Associated with the Formation of Individual Layers” by Lockard
O. U.S. patent application Ser. No. 12/345,624, filed on Dec. 29, 2008, issued as U.S. Pat. No. 8,070,931 on Dec. 6, 2011, and entitled “Electrochemical Fabrication Method Including Elastic Joining of Structures” by Cohen
P. U.S. patent application Ser. No. 14/194,564, filed on Feb. 28, 2014, issued as U.S. Pat. No. 9,540,233 on Jan. 10, 2017, and entitled “Methods of Forming Three-Dimensional Structures Having Reduced Stress and/or Curvature” by Kumar
Q. U.S. patent application Ser. No. 14/720,719, filed on May 22, 2015, issued as U.S. Pat. No. 9,878,401 on Jan. 30, 2018, and entitled “Methods of Forming Parts Using Laser Machining” by Veeramani
R. U.S. patent application Ser. No. 14/872,033, filed on Sep. 30, 2015 and entitled “Multi-Layer, Multi-Material Microscale and Millimeter Scale Batch Part Fabrication Methods Including Disambiguation of Good Parts and Defective Parts” by Le

The teachings in these incorporated applications can be combined with the teachings of the instant application in many ways: For example, enhanced methods of producing structures may be derived from some combinations of teachings, enhanced structures may be obtainable, enhanced apparatus may be derived, and the like.

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may use selective deposition processes or blanket deposition processes on some layers that are not electrodeposition processes. Some embodiments, for example, may use nickel, nickel-phosphorous, nickel-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials.

It will be understood by those of skill in the art that additional operations may be used in variations of the above presented embodiments. These additional operations may, for example, perform cleaning functions (e.g. between the primary operations discussed above), they may perform activation functions and monitoring functions.

It will also be understood that the probe elements of some aspects of the invention may be formed with processes which are very different from the processes set forth herein and it is not intended that structural aspects of the invention need to be formed by only those processes taught herein or by processes made obvious by those taught herein.

Though various portions of this specification have been provided with headers, it is not intended that the headers be used to limit the application of teachings found in one portion of the specification from applying to other portions of the specification. For example, alternatives acknowledged in association with one embodiment, are intended to apply to all embodiments to the extent that the features of the different embodiments make such application functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements, from other embodiments or aspects set forth herein, for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective dependent claims should they be written.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. A pin probe for making electrical contact to an electronic circuit element, comprising:
(A) a pin element, comprising:
(1) a first contact tip;
(2) a second contact tip; and
(3) a compliant portion having a first end functionally connected to the first contact tip, and a second end functionally connected to the second contact tip;
(B) an inner sheath which encases a portion of the pin element without significantly restricting a compliance of the compliant portion along a longitudinal axis of the probe extending from the first contact tip to the second contact tip;
(C) an outer sheath; and
(D) at least one dielectric element that spaces the inner sheath from the outer sheath and provides for electrical isolation of the inner sheath and the outer sheath.

2. The pin probe of claim 1 wherein the compliant portion comprises a multi-turn spring.

3. The pin probe of claim 2 wherein the inner sheath inhibits the multi-turn spring from contacting the outer sheath during compression of one of the first contact tip and the second contact tip toward the other of the first contact tip and the second contact tip.

4. The pin probe of claim 2 wherein the inner sheath comprises a top surface, a bottom surface and two side surfaces that that inhibit non-longitudinal compression of the compliant portion.

5. The pin probe of claim 1 wherein the compliant portion comprises a spring configuration selected from a group consisting of: (1) a rectangular coil; (2) an a plurality of joined S-shaped spring elements; (3) a plurality of compressible and contacting but un-joined compliant elements; (4) a plurality of joined rectangular S-shaped elements; (5) a plurality of S-shaped elements with complete S-shapes defined within a plane of a single layer; (6) a plurality of S-shaped elements with their S-shapes defined by only portions of the S-shape existing within a single layer and a plurality of at least three layers required to define a complete S-shape; (8) a plurality of curved S-shapes with each S-shape having regions of differing width, such that stress within each S-shape is move uniformly applied than it would be for S-shapes of uniform width.

6. The pin probe of claim 1 wherein the at least one dielectric element comprises a plurality of dielectrics spaced along a length dimension of the inner sheath.

7. The pin probe of claim 1 wherein the at least one dielectric element comprises a plurality of dielectric elements separated by a height of the inner sheath.

8. The pin probe of claim 1 wherein the at least one dielectric element comprises a plurality of dielectric elements separated by a width of the inner sheath.

9. The pin probe of claim 1 wherein the inner sheath has a configuration that includes a feature selected from a group consisting of (1) at least one intermediate opening along a length dimension of the inner sheath; (2) a plurality of intermediate openings along a length dimension of the inner sheath; (3) at least one opening along a length dimension of the pin probe wherein each of the at least one opening is located in a position that inhibits the compliant portion from moving into the opening during compression of the compliant portion; (4) at least one opening along a length dimension of the j probe wherein each of the at least one opening has a size that inhibits the compliant portion from moving into the opening during compression of the compliant portion.

10. The pin probe of claim 1 wherein, upon compression of the compliant portion, contact is made between the compliant portion and the inner sheath such that, upon use, current flows between the first contact tip and the second contact tip via the inner sheath.

11. A pin probe for making electrical contact to an electronic circuit element, comprising:
(A) at least two compliant spring elements;
(B) a first pin element having a first end for engaging an electronic circuit element and a second sliding engagement end, wherein the first pin element is connected to first ends of the at least two compliant spring elements; and
(C) a second pin element having a second end for contacting a second electronic circuit element and having a first sliding engagement end, wherein the second pin element is connected to second ends of the at least two compliant spring elements, and wherein the second sliding engagement end of the first pin element and the first sliding engagement end of the second pin element can be made to slidably engage one another upon compression of the first sliding engagement end and the second sliding engagement end toward one another such that a conductive path through the first pin element to the second pin element is provided,
wherein one of the at least two compliant spring elements is located on a first side of the first pin element and the second pin element and the other of the compliant spring elements is located on a second side of the first pin element and the second pin element.

12. The pin probe of claim 11 wherein at least one of the at least two compliant spring elements comprise multi-turn serpentine springs.

13. The pin probe of claim 11 wherein the at least one of the at least two compliant spring elements are compressed as the first pin element and the second pin element are compressed toward one another.

14. The pin probe of claim 11 wherein at least one of the at least two compliant spring elements are stretched as the first pin element and the second pin element are compressed toward one another.

15. The pin probe of claim 11 wherein the at least two compliant spring elements comprise at least four complaint springs.

16. The pin probe of claim 11 wherein the at least two compliant spring elements are inhibited from bowing outward as the first pin element and the second pin element are compressed toward one another.

17. The pin probe of claim 11 additionally comprising an outer sheath relative to which at least one of the first pin element and the second pin element can move, wherein the first pin element and the second pin element are electrically separated from the outer sheath by at least one dielectric spacer.

18. The pin probe of claim 11 wherein the first sliding engagement end and the second sliding engagement end are not in engaged with one another until the first pin element and the second pin element are compressed toward one another and a compliant spring element of at least two compliant spring elements is made to engage a locking element of one of the first pin element and the second pin element.

19. The pin probe of claim 18 wherein the first sliding engagement end and the second sliding engagement end, once engaged, are locked in a slidable position under normal operating conditions.

20. A pin probe for making electrical contact to an electronic circuit element, comprising:
(A) a pin element in functional contact with a first tip and a second tip on opposite ends of the pin element; and
(B) an outer sheath surrounding at least part of the pin element and separated from the pin element by a plurality of dielectric spacers, wherein the outer sheath comprises a plurality of relatively rigid regions spaced longitudinally from one another, and wherein the outer sheath comprises a flexible configuration between the plurality of relatively rigid regions that allows the outer sheath to bend along at least one plane to provide compliance for the pin probe when contacting electronic circuit elements,
wherein the plurality of dielectric spacers are located in at least a portion of the plurality of relatively rigid regions.
